(19) United States
(12) Patent Application Publication
(10) Pub. No.: US 2024/0030380 A1
(43) Pub. Date: Jan. 25, 2024

(54) LIGHT EMITTING DEVICES WITH REDUCED STRAIN

(71) Applicant: Google LLC, Mountain View, CA (US)

(72) Inventors: Melvin Barker McLaurin, Oakland, CA (US); Aurelien Jean Francois David, San Francisco, CA (US)

(21) Appl. No.: 18/355,259

(22) Filed: Jul. 19, 2023

Related U.S. Application Data
(60) Provisional application No. 63/368,919, filed on Jul. 20, 2022.

(51) Int. Cl. H01L 33/12; H01L 33/00; H01L 33/02

(52) U.S. Cl. CPC H01L 33/12; H01L 33/0075; H01L 33/007; H01L 33/025; H01L 33/32

(57) ABSTRACT

In a general aspect, a method for producing an optoelectronic device includes forming a mechanically-compliant layer on a substrate, and forming a second layer, the mechanically-compliant layer being disposed between the second layer and the substrate. The method also includes performing a relaxation operation to facilitate a release of strain energy in the second layer by the mechanically-compliant layer. The mechanically-compliant layer, the second layer and the relaxation operation are configured such that a surface of the second layer has an extended defect density below a predetermined value. The method also includes forming a light-emitting region, the second layer being disposed between the light-emitting region and the substrate. The extended defect density being below the predetermined value results in a leakage resistance in an active region of the light-emitting region that is higher than 10 milliohms per centimeter-squared (mOhm/cm2).

### CROSS REFERENCE TO RELATED APPLICATION

This application claims priority to U.S. Provisional Patent Application No. 63/368,919, filed on Jul. 20, 2022, the disclosure of which is incorporated by reference herein in its entirety.

### TECHNICAL FIELD

This disclosure relates to indium gallium nitride (InGaN) light emitting diodes (LEDs) with reduced strain and devices containing such LEDs.

### BACKGROUND

Light emitting diodes (LEDs), such as micro LEDs, are candidates for use in various display applications, such as smart devices, virtual reality devices, augmented reality devices, etc. In some cases, a combination of III-nitride LEDs emitting blue, green, and red light (radiation) is desirable. However, growing long-wavelength III-nitride light-emitting layers (e.g., red LEDs) can be challenging for several reasons. For instance, such devices are prone to a high amount of defects (point defects, extended defects), which reduce an internal quantum efficiency (IQE) of the device, and can make incorporation of a high amount of indium (In), e.g., for long-wavelength light emission, difficult. These challenges can be worsened by strain in layers used to produce such LEDs. For example, a strain induced by the lattice difference between a gallium nitride (GaN) matrix and associated indium gallium nitride (InGaN) light-emitting layers can lead to defect incorporation and/or creation, and can reduce In incorporation due to lattice pulling.

### SUMMARY

In a general aspect, a method for producing an optoelectronic device includes forming a first layer on a substrate, the first layer being a mechanically-compliant layer. The method also includes forming a second layer, the mechanically-compliant layer being disposed between the second layer and the substrate. The method further includes performing a relaxation operation to facilitate a release of strain energy in the second layer by the mechanically-compliant layer. The mechanically-compliant layer, the second layer and the relaxation operation are configured such that a surface of the second layer has an extended defect density below a predetermined value. The method still further includes forming a light-emitting region. The second layer is disposed between the light-emitting region and the substrate. The extended defect density being below the predetermined value results in a leakage resistance in an active region of the light-emitting region that is higher than 10 milliohms per centimeter-squared (mOhm/cm2).

Implementations can include one or more of the following features or aspects, alone or in combination. For example, the leakage resistance can be greater than 100 mOhm/cm2. The extended defect density can be less than 1×10⁹/cm².

The method can include forming a defect-reduction layer, where the mechanically-compliant layer is disposed between the defect-reduction layer and the substrate.

The mechanically-compliant layer can have a first defect density, and the light-emitting region can have a second defect density that is less than one-tenth of the first defect density.

The relaxation operation can be performed during an epitaxial growth operation.

The optoelectronic device can have a peak internal quantum efficiency of at least 20%.

The optoelectronic device can operate at a current density J and have a leakage current of less than J/10.

The optoelectronic device can operate at a current density J and have an ideality factor of less than 5 at a current density of J/10.

The mechanically-compliant layer can include at least one of a nano-porous structure, voids with dimensions more than 1 nm and less than 1 um, metallic inclusions, extended defects, or semiconductor material with an in-plane inhomogeneity in a composition of one atomic species of at least 1%.

In another general aspect, an optoelectronic device includes a semiconductor template having a first lattice constant, and a strain-relaxation layer disposed on the semiconductor template. The strain-relaxation layer has a second lattice constant which is at least 1% larger than the first lattice constant. The device further includes a defect reduction layer disposed on the strain-relaxation layer, and a light-emitting diode (LED) region including an active region. The LED region is disposed on the defect reduction layer and has a third lattice constant that is substantially equal to the second lattice constant. A surface density of a defect being smaller above the defect reduction layer in a direction of epitaxial growth of the optoelectronic device than below the strain-relaxation layer in the direction of epitaxial growth, such that the LED region has an ideality factor of less than 5 when operating at a current density of 1 A/cm2.

Implementations can include one or more of the following features or aspects, alone or in combination. For example, the strain-relaxation layer can include a plurality of pores respectively having a size between 5 nanometers (nm) and 500 nm.

The device can have an extended defect density that is less than 1×109/cm2.

The device can include a defect-reduction layer. The strain-relaxation layer can be disposed between the defect-reduction layer and the semiconductor template.

The strain-relaxation layer can have a first defect density, and the LED region can have a second defect density that is less than one-tenth of the first defect density.

The strain-relaxation layer can be a grown epitaxial layer.

The strain-relaxation layer can include at least one of a nano-porous structure, voids with dimensions more than 1 nanometer and less than 1 micron, metallic inclusions, extended defects, or semiconductor material with an in-plane inhomogeneity in a composition of one atomic species of at least 1%.

In another general aspect, an optoelectronic device includes a semiconductor template having a first in-plane lattice constant, and a strain-relaxation region disposed on the semiconductor template. The strain-relaxation region includes an inhomogeneous region having a material composition with an in-plane inhomogeneity with a characteristic in-plane distance between 1 nm and 1000 nm. The device further includes a strain-relaxed top surface having dimensions of at least 500 nanometers (nm)×500 nm and a second in-plane lattice constant that is different from the first in-plane lattice constant. The device also includes a light-emitting diode (LED) region disposed on the strain-relaxed top surface. The LED region is pseudomorphic with the strain-relaxed top surface.

Implementations can include one or more of the following features or aspects, alone or in combination. For example, the second in-plane lattice constant can be homogeneous, can have a relative variation of less than +/−10% across the strain-relaxed top surface; and can have an average value that is at least 0.01 angstroms larger than the first in-plane lattice constant.

The in-plane inhomogeneity can vary in composition of an atomic element by at least 1%.

The in-plane inhomogeneity can include at least one of a void, a cavity, a metallic inclusion, or an extended defect.

The device can include a spacer layer having a thickness of more than 10 nm. The spacer layer can be disposed between the inhomogeneous region and the strain-relaxed top surface.

In another general aspect, a method of producing an optoelectronic device includes growing, on a substrate, a series of layers. The series of layers includes at least one relaxation layer under a strain, and a strain-inhibition layer. The at least one relaxation layer is disposed between the strain-inhibition layer and the substrate. After growing the series of layers, the method includes, forming a first lateral region with the strain-inhibition layer having a first thickness, and a second lateral region with the strain-inhibition layer having a second thickness that is greater than the first thickness. After forming the first lateral region and the second lateral region, the method includes performing a relaxation operation, where the relaxation layer changes a mechanical structure of the at least one relaxation layer to reduce the strain in the at least one relaxation layer, such that relaxation in the first lateral region is greater than relaxation in the second lateral region. The method also includes forming at least one light-emitting region on at least one of the first lateral region or the second lateral region.

Implementations can include one or more of the following features or aspects, alone or in combination. For instance, the strain of the at least one relaxation layer can be compressive.

The at least one relaxation layer can include aluminum indium gallium nitride (AlInGaN) material.

The at least one light-emitting region can be formed after performing the relaxation operation.

The first thickness and the relaxation operation can be configured such that the at least one relaxation layer has a predetermined in-plane lattice constant in the first lateral region. That is, the first thickness and the relaxation operation, in combinations, can result in the at least one relaxation layer having a predetermined in-plane lattice constant in the first lateral region.

The first thickness can be zero, such that the strain-inhibition layer is fully removed in the first lateral region.

The at least one relaxation layer can include an indium gallium nitride (InGaN) layer.

Performing the relaxation operation can include forming, in the at least one relaxation layer, at least one of a plurality of nano-pores, a plurality of voids, a plurality of metallic inclusions, a plurality of extended defects, or semiconductor material with an in-plane inhomogeneity in a composition of one atomic species of at least 1%.

In another general aspect, an optoelectronic device includes a first layer disposed on a substrate, the first layer being a mechanically-compliant layer. The device also includes a second layer, the mechanically-compliant layer being disposed between the second layer and the substrate. The second layer is a strain-relaxed layer, as a result of a relaxation operation that facilitates release of strain energy in the second layer by the mechanically-compliant layer. A surface of the second layer has an extended defect density below a predetermined value. The device further includes a light-emitting region. The second layer is disposed between the light-emitting region and the substrate. The extended defect density being below the predetermined value results in a leakage resistance in an active region of the light-emitting region that is higher than 10 milliohms per centimeter-squared (mOhm/cm2).

In another general aspect, an optoelectronic device includes a series of layer disposed on a substrate. The series of layers includes at least one relaxation layer under a strain, and a strain-inhibition layer. The at least one relaxation layer is disposed between the strain-inhibition layer and the substrate. The device also includes a first lateral region with the strain-inhibition layer having a first thickness, and a second lateral region with the strain-inhibition layer having a second thickness that is greater than the first thickness. The at least one relaxation layer, as a result of a relaxation operation, reduces the strain in the at least one relaxation layer, such that relaxation in the first lateral region is greater than relaxation in the second lateral region. The device further includes at least one light-emitting region on at least one of the first lateral region or the second lateral region.

### BRIEF DESCRIPTION OF THE DRAWINGS

FIG. 1A is a diagram that shows a schematic representation of layers of an example device structure.

FIG. 1B is a diagram that schematically illustrates an example of a strain-relaxed state of an epitaxial template after a relaxation process.

FIG. 2A is a diagram illustrating a schematic representation of an equilibrium lattice constant and strain-state after relaxation for various layers in a strain relaxed template.

FIG. 2B is a diagram illustrating a schematic representation of an equilibrium lattice constant and strain-state after relaxation for various layers of a strain relaxed template.

FIGS. 3A and 3B are graphs that compare current-voltage (IV) and efficiency-versus-current of three structures with varying levels of leakage.

FIG. 3C is a graph illustrating a corresponding ideality factor (IF) for each of the three structures of FIGS. 3A and 3B.

FIG. 4A illustrates a structure with an epitaxial template, a strain-relaxation region, and an LED region.

FIG. 4B is a diagram that shows a structure where a defect-reduction region is formed between a strain-relaxation region and an LED region.

FIGS. 5A and 5B are diagrams illustrating respective approaches for dislocation reduction using a selective area growth (SAG) mask.

FIG. 5C is a diagram that illustrates an example of a faceted surface produced by epitaxial growth of an LED region through an aperture of a SAG mask.

FIGS. 6A and 6B are diagrams that illustrate examples of devices with inclined facets that can be produced by etching a surface of a strain-relaxation region, and then subsequently regrowing a mesa region and a device region without a mask.

FIG. 7A is a diagram schematically illustrating an example device implementation with an inhomogeneous strain-relaxation region.

FIG. 7B is a diagram including three graphs illustrating a relationship of strain distribution at three cross-sectional positions in the structure of FIG. 7A.

FIGS. 8A to 8C are diagrams schematically illustrating an example process for achieving relaxation of a base region, e.g., of an LED device structure.

FIGS. 9A to 9C are diagrams schematically illustrating an example process for producing a base region having mesas of varying heights, e.g., of an LED device structure.

FIG. 10A is a diagram that illustrates a device structure wafer where a base region and a relaxation region have been patterned into a plurality of mesas by the etching of trenches in the base and relaxation regions, such as the structure of FIG. 9B.

FIG. 10B is a diagram schematically illustrating a relaxed template with three base region mesas formed from respective sub-regions, e.g., such as the structure of FIG. 8B.

FIG. 11A is a diagram illustrating the example of FIG. 1A, prior to performing a relaxation process.

FIG. 11B is a diagram schematically illustrating the structure of FIG. 11A, where sub-regions are grown pseudomorphic to the template region and corresponding mesas are defined from the sub-regions.

FIG. 12 is a graph illustrating a comparison of relationships between wavelength and internal quantum efficiency (IQE) for various devices.

FIGS. 13A-13E are diagrams illustrating a process with regrowth of LED regions.

FIG. 13F is a diagram schematically illustrating an example of an epitaxial layer stack of a regrown LED.

FIG. 14 is a flowchart illustrating an example process flow for producing LEDs.

FIGS. 15A-15F are diagrams schematically illustrating a process flow for producing LEDs.

FIGS. 16A-16C are graphs illustrating bandgaps and lattice constants calculated for various InGaN and InAlN alloys based on material parameters.

FIGS. 17A-17D are diagrams and graphs illustrating lateral variations in active region properties, e.g., from a center structure to an edge structure.

FIGS. 18A-18C are diagrams illustrating an example process flow for producing LED devices on a relaxed template with a patterned base region.

Like reference symbols in the various drawings indicate like elements. Reference numbers for some like elements may not be repeated for all such elements. In certain instances, different reference numbers may be used for like, or similar elements. Some reference numbers for certain elements of a given implementation may not be repeated in each drawing corresponding with that implementation. Some reference numbers for certain elements of a given implementation may be repeated in other drawings corresponding with that implementation, but may not be specifically discussed with reference to each corresponding drawing. The drawings are for purposes of illustrating example implementations and may not necessarily be to scale.

### DETAILED DESCRIPTION

Implementations described herein are directed to light emitting diode (LED) structures (e.g., micro-LEDs) with reduced strain effects for improving long-wavelength emission. Substrate and growth processes described herein facilitate growth of micro-LED structures with reduced strain, e.g., having strained lattice constants closer to equilibrium lattice constants, which can result in a device with specific electrical, optical, and microstructural qualities to ensure a high performing device.

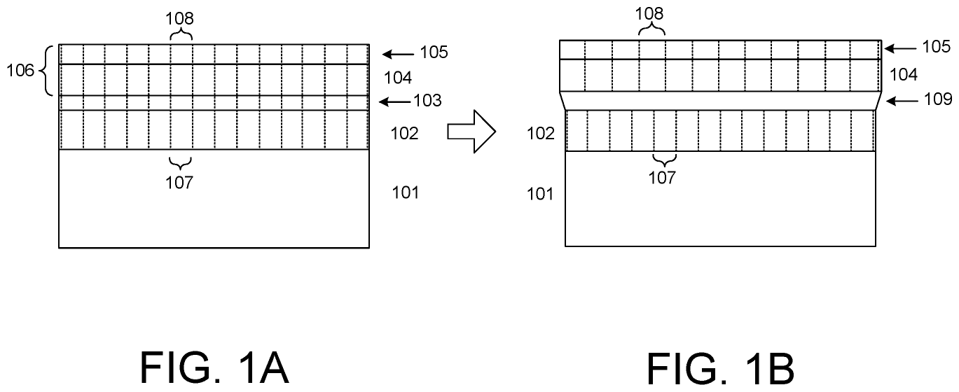

Implementations described herein are directed to LED emitters, or more generally to optoelectronic devices (including LEDs, lasers, super-luminescent LEDs, etc.). Described LED emitter implementations are grown on a strain-relaxed epitaxial template. FIG. 1A, for instance, shows a schematic representation of layers of an example device structure. The strain-relaxed epitaxial template of FIG. 1A includes a substrate 101 (e.g., an epitaxial substrate), and a group III Nitride (III-Nitride) template region 102 that is epitaxially grown on a first surface of the substrate 101, such that a first surface of the template region 102 is in contact with the substrate 101. In the example of FIG. 1A, a strain-relaxation region 103 (a relaxation layer, etc.) is disposed on the template region 102, with a first surface of the strain-relaxation region 103 in contact with a second surface of the template region 102. Further in the example of FIG. 1A, a base region 106 is grown epitaxially on the strain-relaxation region 103 such that a first surface of the base region is in contact with a second surface of the strain-relaxation region 103. As shown in FIG. 1A, the base region 106 can include one or more layers. For instance, in the example of FIG. 1A, the base region 106 include an indium gallium nitride layer (an InGaN layer 104) and a relaxation-inhibition layer 105.

In some implementations, an LED emitter can include pixels, where each pixel can have three subpixels (e.g., respectively emitting blue light, green light, and red light light). Referring to the example of FIG. 1A, at least one layer in the base region 106 of such an LED emitter can be substantially relaxed, and have an indium composition of 50% or less (e.g., 40% or less, 30% or less, 25% or less, 20% or less, 15% or less). In some implementations, the InGaN layer 104 in the base region 106 can be substantially relaxed and have an In composition of 5% or more (e.g., 7.5% or more, 10% or more, 12.5% or more, 15% or more).

In some implementations, the substrate 101 can include sapphire, silicon carbide, quasi-bulk or bulk gallium nitride, silicon, gallium oxide, or lithium aluminate. A surface of the substrate 101 may be functionalized with a material to promote nucleation and growth of subsequent layers. In some implementations, the substrate 101 may have an offcut, including an offcut in a range of 0-3° (e.g., 0-1°, 0.1-1°). For crystals with a wurtzite lattice, the offcut may be along principal crystal directions, such as in a +m direction (or −m direction, +a direction, −a direction, +c direction, −c direction).

In some implementations, the template region 102 is formed on the substrate 101. The template region 102 can include gallium nitride (GaN). In other implementations, the template region 102 can include one or more layers of one or more compositions of aluminum, gallium and/or nitrogen, e.g., with a composition of Al(y)In(x)Ga(1-x-y)N, where y+x=1. The template region 102, which can also be referred to as a buffer layer, can be characterized by a first lattice constant 107 at the template region 102's second surface. The strain-relaxation region 103, and the layers of the base region 106 can be grown such that they are pseudomorphic with the template region 102 and have lattice constants that are within 0.1% of the first lattice constant 107. The base region 106 can have a second surface (e.g., upper surface in FIG. 1A) that has a second lattice constant 108.

In some implementations, the base region 106 includes one or more epitaxially grown layers with one or more compositions of Al(y)In(x)Ga(1-x-y)N where y+x=1. At least one of these layers can be an In(x)Ga(1-x)N layer with x>0.05 or a layer of AlInGaN with a bulk lattice constant equal to or larger than an In(x)Ga(1-x)N layer with x>0.05. In some implementations, the base region 106 can include a single layer. In other implementations, the base region 106 can include a plurality of layers. In some implementations, a first layer of the base region will be GaN or AlGaN, and is grown as a protective cap, or etch-stop layer over the strain-relaxation region 103.

Accordingly, some implementations can be implemented using a growth technique to grow an InGaN-containing base region (e.g., the InGaN layer 104 of the base region 106). For instance, the base region 106 may have one or more layers with an In content of at least 3% (e.g., 5% or more, 8% or more, 10% or more, 12% or more, up to 15%), such as in a range 5-15% (e.g., 5-10%, 10-15%, 5-12%).

InGaN materials can be characterized by their strain state. In some implementations, a region of the InGaN layer 104 is fully relaxed, with a lattice constant (e.g., in-plane and/or vertical) equal to that of InGaN material in its bulk state. While implementations described herein are generally described with reference to the use of InGaN, other materials providing a suitable lattice constant can be used (e.g., AlInN, AlInGaN), according to approaches and techniques disclosed herein.

The base region 106 can be grown as a planar layer, and this planar layer can then be used as-is (e.g., as grown), or can be etched to form lateral structures, such as mesas or nanowires (NWs). In some implementations, such lateral structures can have lateral dimensions of 5 microns or less (e.g., 3 microns or less, 1 micron or less, 500 nanometers (nm) or less, 300 nm or less, 150 nm or less, such as little as 100 nm.

In some implementations, the base region 106 has a plurality of sub-regions. In some implementations, each sub-region can have lateral structures, and the properties of the structures can vary between sub-regions. For instance, dimensions of the lateral structures can vary and/or surface lattice constants of the lateral structures may vary (e.g., some structures can have a lattice constant equivalent to In(x)Ga(1-x)N, where x=0.05, while other structures can have a lattice constant equivalent to In(x)Ga(1-x)N where x=0.10).

In some implementations the lateral structures can be mesas. The mesas can have a height of 10 nm or more (e.g., 50 nm or more, 100 nm or more, e.g., 10 microns or less, 3 microns or less, 2 microns or less, 1 microns or less), such as in a range of 50 nm-10 microns, of 10 nm to 1 micron, of 100 nm to 2 microns, of 500 nm to 3 microns. The mesas can have lateral dimensions of 500 nm or more (e.g., 1 micron or more, such as 20 microns or less, 10 microns or less, 5 microns or less, 3 microns or less), such as in a range from 500 nm to 20 microns, from 1 to 3 microns, from 1 to 5 microns, from 1 to 10 microns.

A cross-section of such lateral structure can have various shapes; which can affect strain relaxation. In some implementations, lateral structures can be elongated (e.g., stripes with lengths larger than their respective widths). Such an approach can facilitate relaxation along the narrower width direction. In some implementations, a lateral structure can have a length L and a width W with L/W>3 (e.g., 5 or more, 10 or more, 50 or more, 100 or more). In some implementations, W<300 nm (e.g., <200 nm, <150 nm, <100 nm, <75 nm, such as low as 50 nm). In some implementations strain can be uniaxially relaxed along a direction of the width. In some implementations, two equivalent crystal directions in a plane of a lateral structure (e.g., two a- or m-directions) can have different amounts of relaxation, with a lattice constant varying by more than 0.1% between the directions. In contrast, in other implementations, lateral structures can have substantially regular shapes (such as a circle, square, triangle or hexagon shapes), which can facilitate biaxial strain relaxation. In some implementations, two equivalent crystal directions in a plane of a lateral structure (e.g., two a- or m-directions) can have equal or similar relaxation, with a lattice constant varying by less than 0.1% between the directions.

A portion of the base region 106 can be characterized by its strain state and/or by its lattice constant. For instance, the base region 106 can have one or more regrowth surfaces, on which an LED region is formed. In some implementations, e.g., where the base region 106 has a single composition, these regrowth surfaces can be fully relaxed, having a lattice constant (in-plane and/or vertical) equal to that of bulk material of a same composition. In some implementations, relaxation is partial, with a lattice constant that is within 1% (e.g., within 0.5%, within 0.3%, within 0.1%, within 0.05%, within 0.03%, within 0.01%) of a bulk material of a same composition. The lattice constant of a bulk relaxed material can be referred to as an equilibrium lattice constant of the material. Relaxation can also be expressed in absolute units rather than relative units. For instance, a relaxed layer (or region) can have a lattice constant which is within 5E⁻³ nm (e.g., within 3E⁻³ nm, within 1E⁻³ nm, within 0.5E⁻³ nm, within 0.1E⁻³ nm) of its equilibrium lattice constant. A pseudomorphic layer (or region) grown on an underlying layer may have a lattice constant which is within 5E⁻³ nm (e.g., within 3E⁻³ nm, within 1E⁻³ nm, within 0.5E⁻³ nm, within 0.1E⁻³ nm) of the underlying layer's lattice constant.

In some implementations, the base region 106 includes a plurality of layers of different compositions with one or more of the layers having an In content of at least 3% (e.g., 5% or more, 8% or more, 10% or more, 12% or more, e.g., up to 15%), such as in a range of 5-15% (e.g., 5-10%, 10-15%, 5-12%). In some implementations, a regrowth surface lattice constant of the base region 106 is within 4% (e.g., within 2%, within 1%, within 0.5%, within 0.1%, within 0.05%, within 0.01%) of an equilibrium lattice constant of a highest indium content layer in the base region 106. Relaxation can also be expressed in absolute units rather than relative units. A relaxed base region 106 can have a regrowth surface lattice constant which is within 1E⁻² nm (e.g., within 5E⁻³ nm, within 1E⁻³ nm, within 0.5E⁻³ nm, within 0.1E⁻³ nm) of its equilibrium lattice constant.

A pseudomorphic layer grown on an underlying layer can have a lattice constant which is within 5E⁻³ nm (e.g., within 3E⁻³ nm, within 1E⁻³ nm, within 0.5E⁻³ nm, within 0.1E⁻³ nm) of the underlying layer's lattice constant.

In some implementations, regrowth surfaces have a low defect density, which can facilitate production of highly efficient LEDs. In contrast, rough regrowth surfaces can lead to three-dimensional morphology of regrown layers. Point defects at or near regrowth can diffuse into regrown layers at growth temperatures. Extended defects such as stacking faults, misfit dislocations, and threading dislocations can propagate into regrown layers and act as sites of non-radiative recombination and/or can affect surface morphology of regrown layers. Extended defects, such as v-pits or inversion domains, can provide paths for undesired shorting of LED devices. Accordingly, example implementations described herein, with reference to FIG. 1A, can have a low defect level in the base region 106. The base region 106 can have a threading dislocation density (TDD) of less than 5E8 cm⁻² (e.g., 1E8 cm⁻² or less, 5E7 cm⁻² or less, 1E8 cm⁻² or less, cm⁻² or less, 1E6 cm⁻² or less). The base region 106 can have a density of stacking faults or misfit dislocations less than 1E5 cm⁻¹ (e.g., 1E4 cm⁻¹ or less, 1E3 cm⁻¹ or less, 1E2 cm⁻¹ or less, 1E1 cm⁻¹ or less). In implementations having lateral structures, a density of defects (including threading dislocations, stacking faults, v-pits, inversion domains, and the like) of less than 500 per lateral structure (e.g., 250 or less, 100 or less, 50 or less, or less) can be achieved.

In some implementations, a final layer of the base region 106 can be a GaN layer or an AlGaN layer, which can be grown as a protective cap on the In-containing layers of the base region, as intermediate operations between fabrication of the strain-relaxed template, e.g., of FIG. 1A, and regrowth of LED device layers can damage In-containing films. For example, wafer cleaning operations incorporating use of acids such as HCl and aqua regia can attack InGaN. As another example, initiation of regrowth can be performed with specific temperature and gas-flow profiles in an epitaxial reactor to ensure proper surface cleanliness of the substrate. Hydrogen, for example, can be used to modify a substrate surface during ramp up of the reactor to growth temperatures. Hydrogen, however, is known to chemically attack InGaN alloys, which can lead to thinning of InGaN layers and roughening of their surfaces prior to the initiation of regrowth of LED device layers. Capping the base region with a GaN or AlGaN layer can prevent such damage as these layers are more resistant to chemical attack.

Areal strain energy density of a film varies linearly with film thickness and varies with a square of in-plane strain. Base region layers (e.g., of the base region 106) with relatively small equilibrium lattice constants, which are under no strain or tensile strain when grown pseudomorphic to the template region, can inhibit expansion of the lattice constant of other InGaN layers. For instance, if one or more operations are performed to relax a lattice constant, this can inhibit the relaxation process. This is due to a reduction in driving force for base region expansion, which is due to release of compressive strain energy in at least one In(x)Ga(1-x)N layer with x≥0.05, such as in the examples discussed above. The inclusion of layers with small lattice constants, which are under no strain or tensile strain when pseudomorphic to the template region 102, results in tensile strain energy being stored in the small lattice constant layers as they are stretched by expanding one or more InGaN layers. Since the driving force for relaxation of the base region 106 (or a layer thereof) is a reduction in the overall strain energy of the base region 106, inclusion of layers put under tension by the expansion of the at least one In(x)Ga(1-x)N layer with x≥0.05 prevent the base region 106 from achieving zero strain energy, and the equilibrium lattice constant for the plurality of layers in the base region 106 will be the one which minimizes the sum of the compressive and tensile strain energy for the plurality of layers in the base region 106.

In some implementations, the strain-relaxation region 103 and the base region 106 are grown pseudomorphic to the template region 102. After the base region 106 is grown, the strain-relaxation region 103 can be modified by one or more processes (called a relaxation process) to render it compliant (mechanically-compliant) such that layers of the base region 106 are able to relax. FIG. 1B is a diagram that schematically illustrates an example of a strain-relaxed state of an epitaxial template after the relaxation process. In this example, the strain-relaxation region 103 becomes a modified strain-relaxation region 109 that is compliant (e.g., mechanically-compliant) and allows a lattice constant of the base region 106 to expand such that the lattice constant 108 at the second surface of the base region 106 is larger than the lattice constant 107 of the template region 102. The InGaN layer 104 and the relaxation-inhibition layer 105 of the base region 106, in this example, are pseudomorphic to each other.

In some implementations, modification of the strain-relaxation region 103 can be achieved in situ, e.g., in a growth reactor in which the base region 106 is grown without first removing the substrate 101, in-process, from the reactor.

In some implementations, modification of the strain-relaxation region 103 can be achieved ex situ to the growth reactor in which the base region 106 is grown. That is, the substrate 101, in process, can be removed from the growth reactor after growth of the base region 106. while the base region 106 is pseudomorphic to the template region 102, and prior to modification of the strain-relaxation region 103.

In some implementations, the strain-relaxation region 103 includes a layer of high indium content Al(y)In(x)Ga(1-x-y)N where y+x=1 and x≥0.20. Layers with such In compositions are stable at low temperatures, but can decompose at elevated temperatures, resulting in formation of a large density of voids within the strain-relaxation region 103. In such instances, while there can be sufficient connectivity remaining between the template region 102 and the base region 106, such that the base region 106 does not detach from the substrate 101 (e.g., from the template region 102), the number of connections may be few enough, that the strain-relaxation region 103 no-longer acts as a rigid connection between the base region 106 and the template region 102.

In some implementations, the strain-relaxation region 103 includes a layer of n-type AlInGaN, where a n-type doping concentration relative to surrounding layers is controlled to allow for selective electro-chemical etching of the strain-relaxation region 103. Under controlled etching conditions, the strain-relaxation region 103 can be partially removed by the electrochemical etch, leaving a porous microstructure with enough remaining material to adhere the base region 106 to the template region 102 without fully constraining the base region 106. The base region 106 can then partially or fully relax. Such an electrochemical etch process can include process operations to etch trenches into the base region 106 (e.g., as in the examples discussed below) to expose the strain-relaxation region 103 to an electrochemical etch solution.

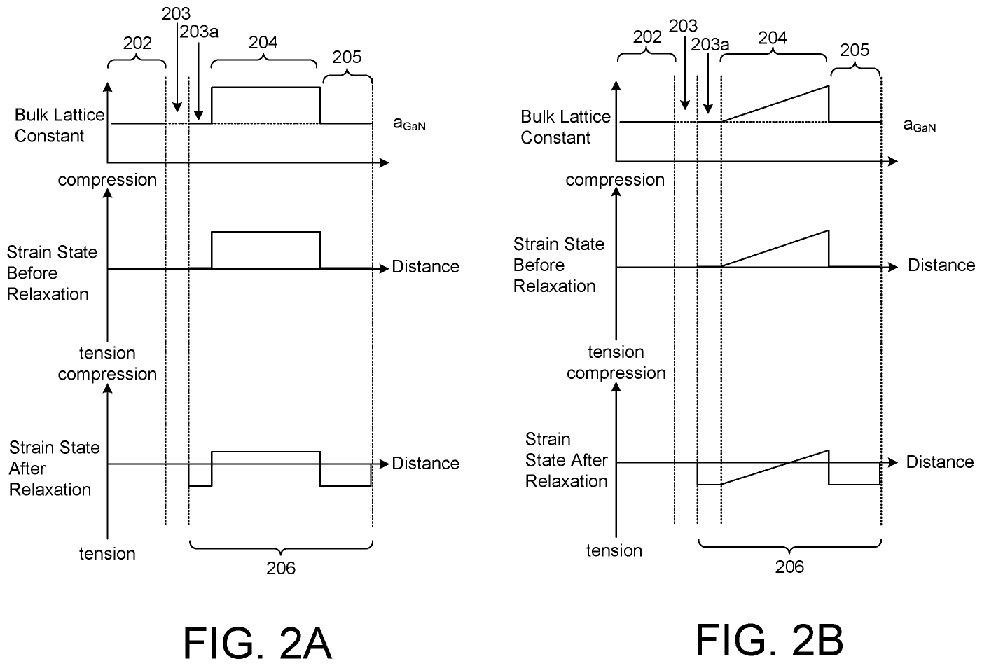

FIG. 2A is a diagram illustrating a schematic representation of an equilibrium lattice constant and strain-state after relaxation for various layers in a strain relaxed template. In this example, the template region is GaN, though in some implementations the template region may include one or more of InGaN, AlGaN, AlN, and/or InAlGaN. In the example of FIG. 2A, an upper section of a template region 202 has an equilibrium lattice constant equal to that of bulk GaN (indicated as a_{GaN}). A strain-relaxation region 203 is illustrated without a strain state due to modification of the associated layer. A base region 206, in FIG. 2A, includes three layers: a GaN protect layer 203a, which separates a layer 204 of the base region 206 from the strain-relaxation region 203. The layer 204 and the relaxation-inhibition layer 205 can include GaN.

Both the GaN protect layer 203a and the relaxation-inhibition layer 205, in this example, are under zero strain prior to modification of the relaxation region 203. After the relaxation process is performed, the lattice constant of the InGaN layer 204 expands, and layers 203a and 205 layers are put under tension. A compressive strain of the InGaN layer 204 is partially relieved, however it cannot be fully relaxed because relaxing further may result in the strain-relaxation region 203 and the relaxation-inhibition layer 205 being put under increased tension.

FIG. 2B is a diagram illustrating a schematic representation of an equilibrium lattice constant and strain-state after relaxation for various layers of a strain relaxed template. In this example, the template region 202 includes GaN, though in other implementations the template region 202 may include one or more of InGaN, AlGaN, AlN, and/or InAlGaN. As shown in FIG. 2B, an upper section of the template region 202 has an equilibrium lattice constant equal to that of bulk GaN. The strain-relaxation region 203 is illustrated without a strain state due to modification of the associated layer. The base region 206 includes three layers, the GaN protect layer 203s, which separates the layer 204, of at least one of the base region 206, from the strain-relaxation region 203. In this example, the layer 204 and a relaxation-inhibition layer 205 of the base region 206 include GaN.

As shown in FIG. 2B, the layer 204 can have a composition graded from GaN to InGaN, such that an equilibrium lattice constant of the layer 204 varies throughout a thickness of the layer 204. Both the GaN protect layer 203a and relaxation-inhibition layer 205 are under zero strain prior to modification of the strain-relaxation region 203, but are both put under tension during a relaxation process due to expansion of a lattice constant of the layer 204 (e.g., InGaN portions of the layer 204). A strain state of the layer 204 will vary with its composition, such that low In content regions of the layer 204 will be under tension, while high In content regions of the layer 204 will be under no-strain, or under a compressive strain.

The relaxation operation may include performing a number of physical processes. For instance, in some examples, a processing operation is performed to modify a mechanical arrangement of a layer, where the layer may be the strain-relaxation region 103. For instance, pores or cavities are formed in the layer. The pores may have an average (or characteristic) size less than 10 nm (or 20 nm, 50 nm, 100 nm, 200 nm, 500 nm, 1000 nm). The pores may have a volume filling fraction in the layer (or “porosity”) in a range 5-50% (or 1-10%, or 10-70%, or 50-95%). The pores may facilitate a compliant mechanical behavior in the layer, allowing the strain-relaxation region 103 to deform locally and to relax strain (e.g., become a modified strain-relaxation region 109). A porosity of 100%, e.g., full removal of the layer, may not be desired as any layers above the porous layer in the epitaxial structure (e.g., layers 104 and 105 above layer 109) would then lack a connection to the substrate wafer preventing them from buckling, forming bubbles, or otherwise peeling off of the substrate. Likewise, too high a porosity may lead to failure of the porous layer due to strain in adjacent layers, which may lead to local or global detachment of the strained layers.

Porous films may be achieved by various techniques, including etching of epitaxial material via chemical, electro-chemical, or photo-electro-chemical processes, or decomposition of the porous layer into one or more liquid or gaseous phases through the application of energy to the at least a portion of (e.g., entire) epitaxial wafer or to the porous layer directly. In some examples, the processing operations (e.g., of the relaxation operation) may be the annealing of the epitaxial wafer at high temperatures, e.g., above 700 degrees Celsius, while in others it may be exposure of the wafer to laser light of a wavelength absorbed strongly by the porous layer but not by surrounding layers. In some examples, a highly focused laser is used. For such a focused laser, the laser wavelength may be absorbed by one or more (e.g., all) epitaxial layers, but the absorbed power density in the porous layer may be controlled by locating the depth of the focal point of the laser at or near the depth of the porous layer in the epitaxial structure. In some examples, a pulsed laser is used (e.g., with nanosecond, picosecond, or femtosecond pulses) to release a high energy rapidly in the crystal. In some examples, the epitaxial wafer is heated through the application of radio frequency or microwave frequency electromagnetic radiation.

In some examples, the porous layer is transparent such that it doesn't contribute significantly to absorption of emitted light from LED device layers, i.e., it has an absorptivity similar to that of surrounding epitaxial layers for the wavelengths of light in the visible spectrum. In some implementations, the porous layer is transparent (e.g., only transparent) at wavelengths corresponding to the violet wavelengths such as 380-420 nm, or the blue wavelengths such as 420-470 nm, or green wavelengths such as 500-570 nm, or to red wavelengths such as 600-650 nm. In some implementations, the epitaxial substrate is removed from the final device, and the porous layer may be fully removed as well. In such cases, the porous layer may not be transparent.

The porous layer (or, more generally, the modified strain relaxation region 109) may be electrically conductive, such that LED device layers overlaying the porous layer can be contacted electrically through the porous layer. Resistive losses in the porous layer can limit a wall plug efficiency of any optoelectronic devices fabricated on the porous layer. The porous layer may have a resistivity of less than 100 Ωcm to limit the excess voltage to less than 0.1 Volts per micron of porous layer thickness for a drive current of 10 A/cm². Conductivity of the porous layer can be controlled by one or more of adjusting the doping concentration of the AlInGaN material remaining in the porous layer, controlling the volume fraction of porosity in the porous film, and/or controlling the degree of percolation of voids in the porous layer. In some implementations, the porous layer resistivity is less than 1000 Ωcm (or less than 500 Ωcm, less than 100 Ωcm, less than 10 Ωcm).

In some examples, the modified strain relaxation region 109) introduces no new extended defects into the device layers above it. In some implementations, the device layers above the modified relaxation region 109 are characterized by a dislocation density that is less than or equal to 150% of that of the template region.

Surface pits and other extended-defects intersecting the surface may be characterized by the number of defects per unit of area on the surface of the wafer. In the case of defects where the morphology of the epitaxial film at the surface is altered by the presence of the defect, the defects can be imaged by the use of scanning microscopy techniques such as atomic force microscopy [AFM] or electron microscopy such as scanning electron microscopy [SEM] with contrast derived from secondary electrons, backscattered electrons, or cathodoluminescence. Characterization of the defect density in or just below the active region of the device prior to the growth of any overlaying layers such as p-type conduction layers can be desirable. It is possible that defects such as pits might be present during the growth of the active region and effect the morphology of the active region while growth of subsequent layers may be under conditions that eliminate morphologies characteristic of the pits or defects. Characterization techniques such as cathodoluminescence, which image contrast from non-radiative recombination near defects will reveal defects such as threading dislocations even when the defects do not modify the film morphology.

In some implementations, a device is characterized by a low defect density that facilitates a low leakage. It is known that some structural defects can make a device leaky, for instance if the defects create a shunt path through the active region of the device. Such defects may be created by compliant layers during a strain relaxation operation, which may be undesirable. Implementations improve upon this by providing appropriate means to reduce the defect density and facilitate a low leakage.

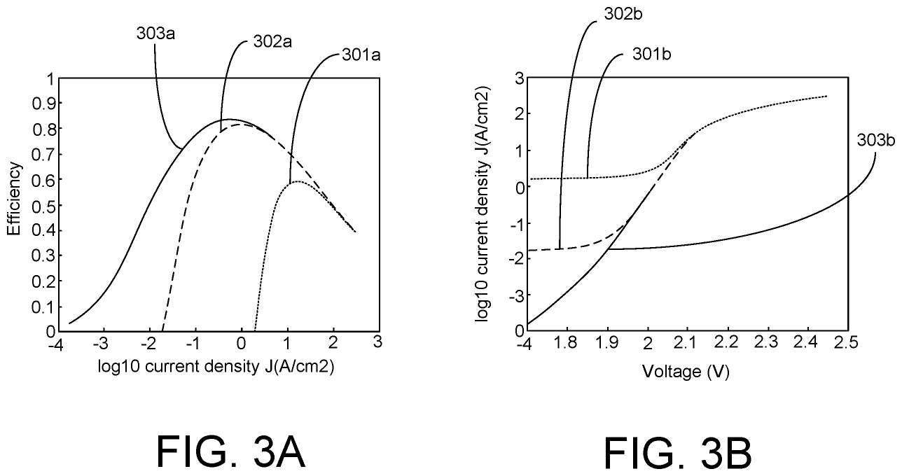

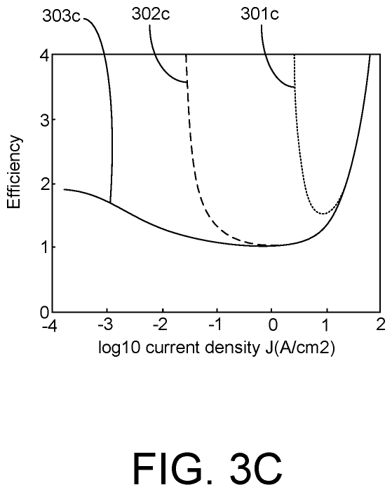

FIGS. 3A and 3B are graphs that compare current-voltage (IV) and efficiency-versus-current of three structures with varying levels of leakage. In this example, a trace 301a (FIG. 3A) and a trace 301b (FIG. 3B) correspond with a first structure. A trace 302a (FIG. 3A) and a trace 302b (FIG. 3B) correspond with a second structure. A trace 303a (FIG. 3A) and a trace 303b (FIG. 3B) correspond with a third structure. Comparatively, the first structure has the highest amount of defects, which cause leakage and suppress IQE, while the third structure has the lowest amount of defects, resulting in lower leakage and a higher IQE. In this example, the active region of each illustrated structure is a red-emitting quantum well (e.g., with a band gap of 2 eV or emission wavelength of 620 nm), with recombination parameters providing a peak internal quantum efficiency (IQE) of 83% (at an operating current density of 0.5 amps per centimeter-square (A/cm²)), in the absence of leakage. A corresponding LED can have a series resistance of 1 milliohms per centimeter-squared (mOhm/cm²).

As shown by the trace 301a and the trace 301b, the first structure has a relatively large leakage current, with a shunt resistance of 1 Ohm/cm². This causes leakage up to a current density of a few A/cm², which suppresses its IQE. For instance, a peak IQE of the first structure is less than 60%, at a current density of 20 A/cm². As shown by the trace 302a and the trace 302b, the second structure has a relatively moderate leakage, with a shunt resistance of 100 Ohm/cm², which causes a leakage current up to a current density of a few tens of mA/cm², and a suppression of the second structure's IQE, especially at low current densities, e.g., below 100 mA/cm². As shown by the trace 303a and the trace 303b, the second structure has no leakage (e.g., near zero leakage) and, as a result, a non-leaky IV curve with a high IQE, even at low current densities, e.g., below 100 mA/cm².

FIG. 3C is a graph illustrating a corresponding ideality factor (IF) for each of the three structures of FIGS. 3A and 3B. A trace 301c illustrates an IF for the first structure, a trace 302c illustrates an IF for the second structure, and a trace 303c illustrates an IF for the third structure. For the third structure, IF=2 at low current (in the Shockley-Read-Hall regime), IF=1 at intermediate currents (where radiative recombination dominates) and IF becomes high at high current density due to the series resistance of the device.

Some implementations have a reduced defect density which facilitates a low leakage and a high IQE. Modification of the epitaxial process and structure (e.g., growth condition, layer thickness, composition) can lead to a reduction in defect density (e.g., point defects or extended defects). Accordingly, the evolution from the first structure to the third structure of FIGS. 3A-3C illustrates LED implementations with reduced leakage. For the second structure and the third structure, IF increases in a higher leakage region. Accordingly, IF can be an indicator of leakage. Some implementations operate at a current density Jₒₚ (current density J, etc.), and have an ideality factor less than 10 (or 5 or 3) at a current density Jₒₚ/10 (or Jₒₚ/20, Jₒₚ/100, Jₒₚ/200, Jₒₚ/1000). Some implementations operate at a current density in the range 0.1-100 A/cm², and have an IF less than 10 (or less than 5, less than 3) at a current density of 1 A/cm² (or 0.1 A/cm2, A/cm²).

Some implementations can include a device operated at a current density Jop (in A/cm2), with a leakage current that is less than 20% (or 10%, 2%) of Jop. Some implementations can include a device operated at a current density Jop, with a leakage resistance (in ohm/cm2) that is at least 10 volts/Jop (or 20 volts/Jop, 100 volts/Jop). In some implementations, the device may have an IQE of at least 30% (or 50%, of 70%) when operated at Jop. Some implementations can include a device operated at a current density Jop, whose ideality factor is less than 10 (or 5, or 3) at a current density Jop/10.

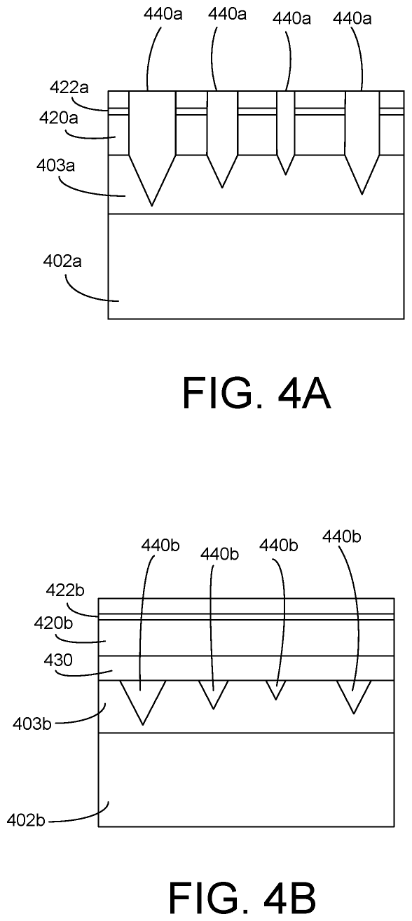

FIGS. 4A and 4B are diagrams showing two contrasting potential epitaxial structures. FIG. 4A illustrates a structure with an epitaxial template 402a (for instance GaN or another III-nitride material); a strain-relaxation region 403a, in which defects 440a can occur (e.g., can be formed), and an LED region 420a including an active region 422a disposed on (above) the strain-relaxation region 403b. The strain-relaxation region 403b provides (results in, causes, etc.) reduced strain in the active region 422a. However, defects in the strain-relaxation region 403a propagate through the epitaxial stack of the LED region 420a and into the active region 422a, causing leakage.

FIG. 4B shows a structure where a defect-reduction region 430 is formed between a strain-relaxation region 403b and an LED region 420b. As compared to FIG. 4A, the defect-reduction region 430 suppresses propagation of defects 440b from a strain-relaxation region 403b, reducing their presence in the active region 422b, and facilitating a lower leakage than the structure in FIG. 4A. The structure of FIG. 4B, as with the structure of FIG. 4A, includes an epitaxial template 402b and a strain-relaxation region 403b. In some implementations, such as implementations of the structure in FIG. 4B, a density of defects 440b has a first value in the strain-relaxation region 403b, and a second value in the active region 422b, where the second value is less than 1/10 (or less than 1/100, or less than 1/1000) of the first value. Approaches for reducing a defect density include semiconductor processing operations for reducing a number of defects, and/or processing operations for reducing respective sizes of defects in active region 422b Examples of such processing operations are described herein.

In some implementations, defects (e.g., respective sizes and number of defects), such as defects 440a and defects 440b, can be reduced by use of growth conditions that reduce the size of, or eliminate pits in an associated epitaxial surface. For instance, AlInGaN films (e.g., epitaxially grown layers) are known to exhibit pits, which often decorate (e.g., are formed around) extended defects, such as threading dislocations. The size of the pits can be modified by the use of such specific growth conditions. In some implementations, pits are present in one or more strain relaxation layers, e.g., the strain-relaxation region 403a or the strain-relaxation region 403b. Growth conditions can be chosen to reduce the size of pits or eliminate pits. This may occur during growth of the active region itself (the active region 422a or the active region 422b), and/or during growth of layer that are grown subsequent to the growth of a relaxation layer (e.g., the defect-reduction region 430), but prior to growth of the active region of an associated LED.

Such growth conditions can include growth pressure, a surfactant species such as indium or aluminum, and a carrier gas species such as hydrogen. Potential growth conditions can also include use of pulsed growth conditions, inclusion of one or more GaN or AlGaN interlayers, inclusion of one or more InGaN layers grown with a composition placing the InGaN layer under tension, growth of interlayers at elevated temperature, growth interlayers using hydrogen as a carrier gas, growth of InGaN layers at elevated temperature, which may include the ratio of In precursor to Ga precursor molar ratios elevated to maintain the InN content of the resulting film, modification of the V/III ratio, among other potential growth conditions.

As one example, in some implementations, small amounts of hydrogen gas can be used along with nitrogen as a carrier gas during growth of InGaN films. When present in large concentrations, hydrogen gas can cause decomposition of InGaN, and can limit incorporation of InN into the growing film. Low concentrations of hydrogen added to the carrier gas (e.g., nitrogen) can reduce the size and/or number of pits in growing InGaN films. A low concentration of hydrogen in the carrier gas may correspond to a ratio of hydrogen flow/nitrogen flow less than 0.1 (or 0.01, 0.001).

In some implementations, at least one defect-reducing layer may be included, such as the defect-reduction region 430 in FIG. 4B. In some implementations, the defect-reduction region 430 can include porous masking layers, such as silicon nitride, silicon oxide, or other dielectric, ceramic, or metallic films. Masking layers may be deposited either in situ or ex situ to an epitaxial growth reactor. Pores in such masking layers, e.g., of the defect-reduction region 430 may either be formed during an associated deposition process, or subsequently formed in the masking layer using an etch or lift-off process either, with or without lithographic patterning. In example implementations, masking layers (e.g., the defect-reduction region 430) can block propagation of extended defects, such as threading dislocations and stacking faults from epitaxial layers below the masking layer(s) to epitaxial layers above the masking layer(s), e.g., from the strain-relaxation region 403b to the LED region 420b of the example of FIG. 4B.

Threading dislocations in wurtzite nitride semiconductors, and especially in (0001) oriented films, have line directions substantially parallel to a growth direction of the film, e.g., an epitaxial growth direction. Intersections of multiple threading dislocations, which may lead to dislocation fusion or annihilation are, therefore, relatively unlikely. Accordingly, it can be difficult to reduce a dislocation density of a film by dislocation reaction when the film is thin. Disclosed implementations can help overcome this difficulty by providing methods to reduce dislocations, as well as other extended defects.

In some implementations, a defect-reduction region, e.g., the defect-reduction region 430 can include one or more layers with composition and or growth conditions chosen to encourage annihilation of threading dislocations, thus reducing an associated threading dislocation density in a subsequently grown active region, e.g., the active region 422b in FIG. 4B.

In some implementations, growth conditions can be selected to cause gliding of threading dislocations, where such gliding results in the formation of misfit dislocations. When gliding threading dislocations intersect, they may either fuse into a single threading dislocation or annihilate each other, leaving behind a dislocation loop that is buried in an associated epitaxial structure. For instance, growth of layers (e.g., epitaxial layers) under large compressive or tensile strain can induce dislocation glide. Dislocation glide can also be promoted by annealing strained layers at elevated temperatures, as dislocation glide is a kinetic process. Such an annealing operation can be performed on layer grown with specific growth conditions, e.g., to prevent degradation of an associated strained layer during the anneal. Such growth conditions can include elevated V/III ratios, using indium as a surfactant, selection of a carrier gas, adjusting a growth pressure, and so forth.

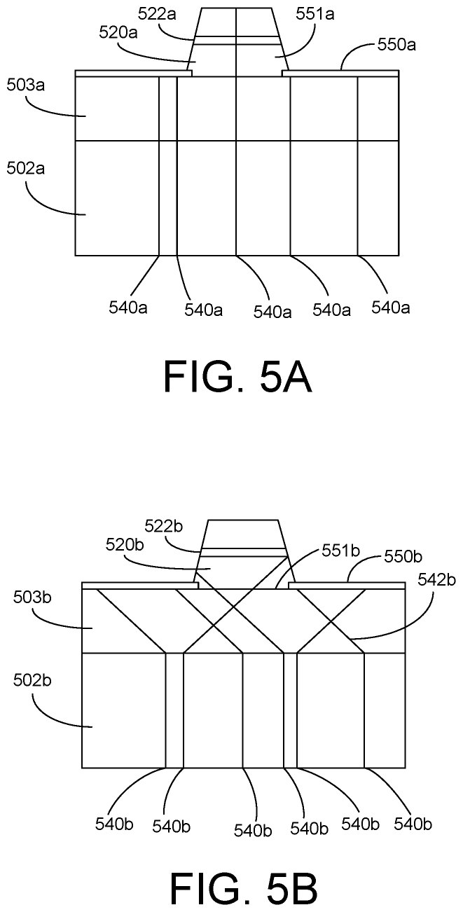

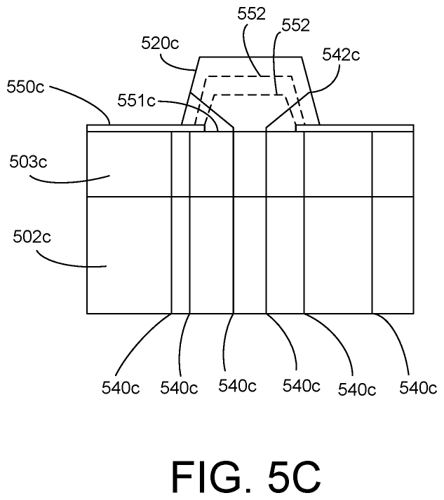

In some implementations, dislocation reduction can be achieved by growth through a selective area growth (SAG) mask. For instance, FIGS. 5A and 5B are diagrams illustrating respective approaches for dislocation reduction using a SAG mask 550a (FIG. or a SAG mask 550b (FIG. 5B). In the example of FIG. 5A, a template region 502a containing threading dislocations 540a is overgrown by a strain-relaxation region 503a. In this example, an associated epitaxial wafer can be removed from an epitaxial growth chamber and the selective area growth (SAG) mask 550a can be deposited on the epitaxial surface, e.g., of the strain-relaxation region 503a, and patterned (using photolithography processes) to form apertures (e.g., aperture 551a) exposing underlying group-III nitride material (e.g., of the strain-relaxation region 503a or other epitaxial layer.

Subsequent growth on the substrate, after formation of the SAG mask 550a, can then result in selective epitaxial deposition at the aperture 551a (e.g., only at such apertures) of the SAG mask 550a. That subsequent growth can result in formation of mesa regions, e.g., an LED region 520a and an active region 522a, of AlInGaN material with limited lateral extent as defined by the aperture 551a. As shown in FIG. 5A, the SAG mask 550a can block threading dislocations, e.g., threading dislocations disposed under the SAG mask 550a and not within the aperture 551a. In some implementations, the AlInGaN mesas can be grown under conditions that promote lateral growth to enable an active region area larger than an area of an associated SAG mask 550a aperture.

In some implementations, apertures, such as the aperture 551a, can be significantly longer in one dimension than in a second dimension, e.g., a dimension that is orthogonal to the first dimension. In some implementations, the first dimension of an aperture can correspond to a major axis of an edge emitting laser cavity.

In some implementations, such as in the example of FIG. 5B, strain in a strain relaxation layer (e.g., in a strain-relaxation region 503b) can result in tilting of respective line directions of threading dislocations, e.g., as shown by inclined portions 542 in FIG. 5B. This tilting can be energetically favorable for dislocations with Burgers vectors that contain a component normal to a strained film growth direction (e.g., epitaxial growth direction) such that the inclined portions 542 of threading dislocations relieve some strain in the strained film in a similar way as a misfit dislocation.

In the example of FIG. 5B, the inclined portions 542 of threading dislocations 540b start at an interface of a strain-relaxation region 503b and a template region 502b. In some implementations, a SAG mask 550b is defined (formed, produced, etc.) such that the inclined portions 542 of the threading dislocations 540b are either blocked by the SAG mask 550b or, if the dislocations are sufficiently inclined relative to the epitaxial growth direction, can extend through an aperture 551b in the SAG mask 550b, and terminate at a sidewall of a mesa of the LED region 520b (e.g., and before an active region 522b). In this example, the active region 522b, e.g., grown as part of a mesa of the LED region 520b can have a substantially reduced dislocation density. In some implementations, the inclined portions 542 of the threading dislocations 540b are inclined by 45 degrees or more (or 20 degrees or more, or 10 degrees or more).

In some implementations, such as the examples of FIGS. 5A and 5B, dislocation reduction can be achieved using three-dimensional growth of AlInGaN, e.g., during growth of the region 503b, where faceted surfaces, such as sidewalls of pits, or AlInGaN islands result in bending of dislocation line directions (e.g., the inclined portions 542b) toward the sidewalls of a mesa formed using, e.g., the SAG mask 550b. This bending can increase a rate at which dislocations intersect, e.g., a thickness of, e.g., the strain-relaxation region 503b, increases. Forming the structure of FIG. 5B may include performing a planarization operation that results in reestablishing two-dimensional growth (from a three-dimensional growth process operation) on a substantially planar surface prior to growth of the active region 522b.

In some implementations, a faceted surface can be produced as a result of growth through an aperture of a SAG mask. For instance, FIG. 5C is a diagram that illustrates an example of a faceted surface produced by epitaxial growth of an LED region 520c through an aperture 551c of a SAG mask 550c. In the example of FIG. 5C, a strain-relaxation region 503c containing threading dislocations 540c is overlaid by the SAG mask 550c with the aperture 551c. Dislocations passing through the aperture 551c grow near the inclined sidewalls of the resulting mesa and are inclined towards the sidewalls due to a net reduction in total energy due to shortening of a line length of the threading dislocations. Device layers subsequently grown on the top of previously grown device layers, as indicated by intermediate growth points 552, or as part of the mesa can then contain a substantially reduced density of dislocations. In some implementations, apertures, such as the aperture 551c are significantly longer in a first dimension than in a second dimension, with the first dimension of the aperture corresponding to the major axis of an edge emitting laser cavity, such as discussed above with respect to, at least, FIG. 5A.

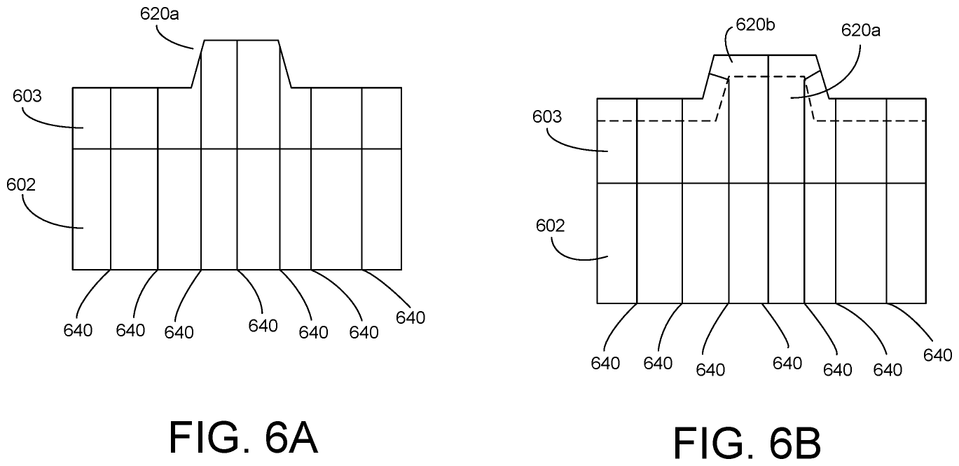

FIGS. 6A and 6B illustrate examples of devices with inclined facets that can be produced by etching a surface of a strain-relaxation region 603 containing threading dislocations 640, and then subsequent mesa region 620a and device region 620b regrowth without a mask. As shown in FIGS. 6A and 6B, the dislocations 640 near a sidewall 621 of a mesa 620a will bend to intersect the inclined sidewall surface of a device region 620b, rather than continue to propagate upward. Such an approach can substantially reduce a number of dislocations intersecting with top surface of the device region 620b mesa, e.g., where device layers of an LED device will be subsequently grown. In some implementations, an etched mesa is significantly longer in a first dimension than in a second direction orthogonal to the first direction, with the first dimension of the mesa corresponding to the major axis of an edge emitting laser cavity.

In some implementations, an anneal operation can be performed on the structure of FIGS. 6A and 6B, e.g., to induce dislocation glide and the formation of misfit dislocations. As described herein, dislocation glide is driven by elevated temperature and reduction of strain energy due to formation of misfit dislocations connecting a glissile portion and a sessile portions of threading dislocation(s). For instance, such dislocation glide can cause the glissile portion of a threading dislocation (e.g., dislocations 640) to move to the edge of a mesa, where the dislocations can then terminate at a sidewall of the mesa.

The following discussion is directed to various features or aspect that can be included in one or more of the implementation described herein. For example, in some implementations, a SAG mask is a non-patterned mask such as porous silicon nitride, silicon oxide, metal such as W, Ti, or Mo.

In some implementations, threading dislocations originate from the strain relaxation process and layers grown overlaying the strain-relaxation region have higher threading dislocation densities than the template layers.

In some implementations, dislocation reducing elements are processed into layers grown subsequent to the strain-relaxation region but prior to the light emitting layers.

In some implementations, a dislocation density in the device region is reduced by a predetermined amount during a density-reduction operation (process, etc.), as described above. For instance, the density after the density-reduction operation is less than 20% (or 10%, 1%, 0.1%) of the density before the density-reduction operation.

In some implementations, strain is relaxed during the density-reduction operation.

In some implementations, growth conditions in the defect-reduction region are selected to reduce or eliminate metal species accumulated on the epitaxial growth surface. In some implementations, a pause in growth is performed to provide time for the metal species to desorb. Growth conditions during the pause may be selected to either promote desorption of the undesired metal species and/or to protect the epitaxial surface from degradation during the pause. Growth condition changes that may promote desorption include an increase in the substrate temperature, an increase in the V/III ratio significantly or pause of the flow of one or more group III precursor species to the growth chamber, a change in the ratio of hydrogen to nitrogen in the carrier gas mixture, a reduction in the growth chamber pressure, among others.

Other approaches can be implemented to reduce defects. The defects may be of various types, including dislocations (including threading dislocations of screw and/or mixed type), dislocation loops, stacking faults, domains of inverted crystal stacking sequence or stacking mis-match boundaries, v-pits, metallic inclusions (including In, Ga, Al), voids. point defects (such as vacancies or In, Ga, Al, or N interstitial atoms), micropipes, open-core dislocations, among others.

In some implementations, strain relaxation is elastic, in that the relaxation occurs by way of the expansion or contraction of the lattice without the introduction of extended crystal defects. In general, elastic relaxation is difficult to achieve because at one or more (e.g., all) points on an associated epitaxial surface the strained layer is constrained by the layer beneath it due to atomic bonds between layers. The introduction of extended defects, such as misfit dislocations, break these bonds and enable the strained film to partially relax. Elastic relaxation can require the strained film to be decoupled from the substrate. This is achieved by the introduction of a relaxation layer which can be modified to make it compliant such that the relaxation layer will connect the strained layer to the substrate while also allowing the strained layer to expand or contract to relieve strain energy.

In some implementations, the relaxation mechanism transforms the relaxation region in at least one of the following ways, a change in composition, a change in homogeneity, a change in density, or a change in local atomic concentration,

In some implementations, the relaxation region includes a highly-doped layer of GaN, AlGaN, or InGaN. Electrochemical etching is used to selectively etch the layer such that the layer is modified to have a microstructure characterized by the presence of voids. The porosity of the modified layer is chosen such that the volume fraction of pores is high enough such that the remaining material easily stretches to accommodate the relaxation of the strained layer, while keeping the porosity low enough that the strained layer is not fully undercut and able to separate from the substrate.

In another implementation, the relaxation region includes a composition of InGaN or InAlN or InGaAlN layers with a relatively high fraction of InN. The relaxation region is modified by exposing it to elevated temperatures such that the InN-containing relaxation region partially decomposes with a microstructure characterized by voids containing In and Ga metal. A porosity of the modified relaxation region is chosen such that the volume fraction of pores is high enough that the remaining material easily stretches to accommodate the relaxation of the strained region while keeping the porosity low enough that the strained layer is not fully undercut and able to separate from the substrate.

In some implementations, the relaxation region includes a composition of InGaN or InAlN or InGaAlN layers with a relatively high fraction of InN. The relaxation region is modified by exposing it to elevated temperatures such that the InN-containing relaxation region fully decomposes with a microstructure characterized by regions of varying mixtures of In and Ga metal. The Ga and In metal are liquid at epitaxial growth temperatures, and indeed are liquid at temperatures above the range of ˜15 to ˜160° C. depending on the composition of the In and Ga alloy. The In and Ga alloys will flow, allowing the strained region to relax by expansion or contraction while the thickness of the modified relaxation region is chosen such that the adhesive forces between the substrate, the metal regions, and the strained region prevent the strained region from delaminating from the substrate surface.

In some implementations, a strain-relaxation region is characterized by a non-uniform spatial composition, such as a nano-porous III-nitride layer, with air pores having typical dimensions in a range 1-1000 nm (or 1-300 nm, 10-500 nm, or 50-500 nm), a III-nitride layer containing a sufficiently high fraction of In (at least 10% or 20% or 30% or 40% or 50%) (where the In forms metallic defects and voids), or a semiconductor layer having an inhomogeneous in-plane composition, with the composition of a least one atomic species varying by at least 1% (or 5%, or 10%), for instance, an AlInGaN layer where the In composition varies in-plane.

Although the examples discussed above focus on the III-nitride family, other known semiconductor systems (such as AlInGaAsP) can be used. For instance, other metallic atoms can replace In.

A non-uniform composition may be achieved by operations including etching (e.g., chemical, photo-chemical, electro-chemical, or photo-electro-chemical etching), performing a thermal operation, application of optical energy, and so forth.

The non-uniform composition may facilitate relaxation of strain energy.

The non-uniform composition may have a typical (or ‘characteristic’) lateral scale. This scale describes an order of magnitude over which non-uniformity is observed. It may be an average of respective distances between non-uniform regions.

In some implementations, a scale of the non-uniformity is sufficiently small that it does not result in an inhomogeneous lattice constant far enough above the strain-relaxation region. In some implementations, the non-uniform region is covered by one or several capping layers of sufficient thickness to homogenize the in-plane lattice constant. The thickness of the capping layers may be at least 1× (or 5×, 10×, 50×, 100×) the characteristic lateral scale of the non-uniformity.

In an example implementation, an optoelectronic device can be produced as follows:
1. A strain-relaxation region is formed.
2. A relaxation operation is performed to relax the strain-relaxation region, causing inhomogeneity in the strain-relaxation region with a characteristic lateral scale.
3. At least one capping layer is grown on the relaxation region, with a thickness at least equal to 1× (or 10×, 100×) the lateral scale.
4. An active (e.g., LED) region is grown on the capping layer.

For clarity, in the sequence above, the order of some operations may be modified. For instance, a first capping layer may be grown on the strain-relaxation region before the relaxation operation, followed by further growth after the relaxation operation. The active region may be pseudomorphic with the relaxed strain-relaxation region.

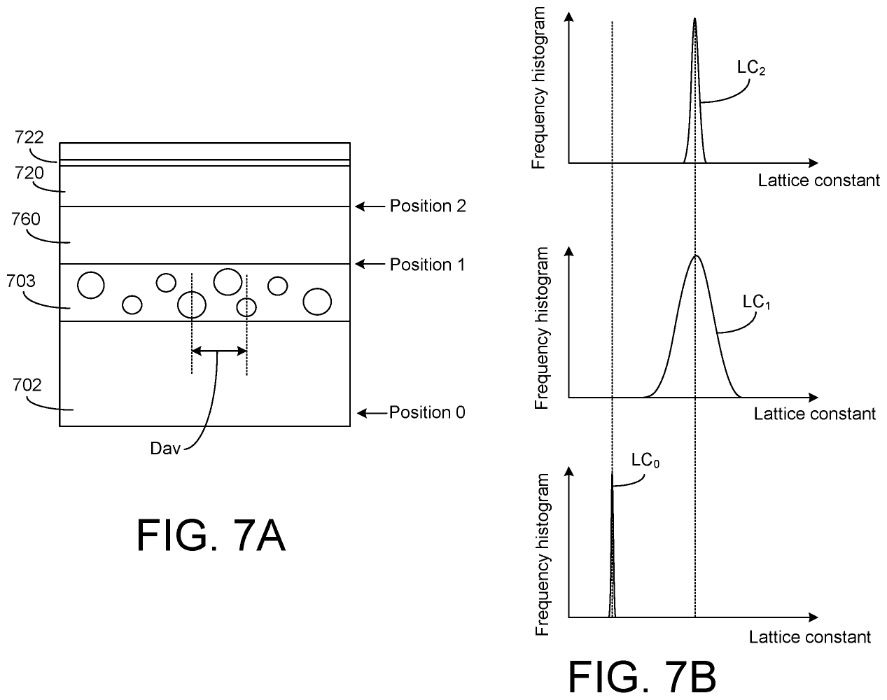

FIG. 7A is a diagram schematically illustrating an example device implementation with an inhomogeneous strain-relaxation region 703. The inhomogeneous strain-relaxation region 703, which is disposed on a template region 702, such as those described herein, has inhomogeneous features 703a. The inhomogeneous features 703a can include pores, voids, and/or zones (areas, portions, etc.) having different material compositions. In this example, the inhomogeneous features 703a are separated by an average distance Day. Such an arrangement can cause an inhomogeneous lattice constant distribution in and above the inhomogeneous strain-relaxation region 703, e.g., in the view of FIG. 7A. In this example, a cap layer 760 is formed (e.g., disposed, located, etc.) between the strain-relaxation region 703 and an active region 722, which can be included in a device region 720. In some implementations, the cap layer 760 can facilitate a more homogeneous lattice constant distribution in layers above the cap layer, e.g., in the active region 722.

FIG. 7B includes three graphs illustrating a relationship of strain distribution at three cross-sectional positions in the structure of FIG. 7A, a position 0, position 1, and a position 2. In this example, at position 0 (e.g., in the template region 702), as illustrated by a trace LC₀, a lattice constant has a well-defined value, for instance, that of relaxed GaN. At position 1 (at an upper surface of the strain-relaxation region 703), as illustrated by a trace LC₁, an average lattice constant is larger, e.g., due to relaxation, but has a wider distribution. For instance, a full-width at half a maximum of this distribution may have a first value above 0.00001 angstroms (Å) (or 0.00005 Å, 0.0001 Å, 0.0005 Å, 0.001 Å). The first value may be at least 1% (or 10%) of a difference in average lattice constants between positions 0 and 1. At position 2, above the cap layer 760, as illustrated by a trace LC₂, an average lattice constant is the same as at position 1 (e.g., indicating that the average lattice constant does not change across cap layer 760). However, variation in the lattice constant at position 2 is reduced and has a narrower distribution. For instance, a full-width at half a maximum of this distribution may have a second value less than 0.0001 Å (or 0.00005 Å, 0.00001 Å, 0.000005 Å, A). The second value may be less than 1% (or 0.1%) of a difference in average lattice constants between positions 0 and 2. Position 2 may be termed a “homogeneous surface”.

The following discussion is directed to various features or aspect that can be included in one or more of the implementation described herein. For example, in some implementations, a layer above the cap layer (e.g., the active region 722) has an in-plane lattice constant whose statistical distribution is dominated by its random alloy distribution.

The homogeneity of a lattice constant may be evaluated over regions of appropriate dimensions. For instance, a planar region of the active region 722 having an extent of at least 100×100 nm (or 500×500 nm, 1×1 um, 5×5 um, 10×10 um, 50×50 um) may be considered to assess the homogeneity. In some examples, a strain-relaxation region (e.g., the region 703) has inhomogeneous features (e.g., voids) with a typical lateral dimension less than 1 nm (or 5 nm, 10 nm, 20 nm, 100 nm, 200 nm, 500 nm, 1 um), and the homogeneous surface is homogeneous over a lateral dimension that is sufficiently large compared to this typical lateral dimension (e.g., 1×, 2×, 5×, 10×).

The width of the lattice constant distribution (as shown in FIG. 7B) may be measured in an XRD measurement (such as a reciprocal space map measurement, or a grazing incidence XRD measurement). Grazing incidence XRD measurements are capable of characterizing an in-plane lattice constant of a film as a function of depth. Below a critical angle, typically <1 degree, the grazing incidence X-rays can be totally externally reflected and penetration depths are limited to a few nanometers of material. At higher angles, penetration depths of up to several microns are possible with the appropriate measurement systems. Strain inhomogeneity can also be estimated from a peak width of omega-2theta XRD scans of the on-axis peaks using the standard Williamson-Hall analysis that separates the contributions of an inhomogeneous strain distribution from the vertical coherence length of the film. Williamson-Hall analysis can also be performed on in-plane X-ray peaks measured with grazing incidence X-ray diffraction.

The width of the lattice constant distribution (as shown in FIG. 7B) may be measured in cross-sectional transmission electron microscopy (TEM). Lattice spacing can be measured locally in TEM using high-resolution imaging conditions, with lattice spacing distributions determined from measuring lattice spacing at various points within the TEM foil. Lattice spacing can also be measured by imaging the electron diffraction pattern of a TEM foil and performing Williamson-Hall-style analysis on the diffraction peak widths as a function of position in reciprocal space as is done in XRD analysis of thin films.

For highly compliant strain-relaxation regions, it may be possible for the strained film when under compression to relieve strain with both lateral, uniform expansion as well as buckling out of the plane of the film. Buckling will produce a corrugated surface comprising peaks and valleys separated by a characteristic length. Buckling will introduce increased strain energy at the peaks and valleys where curvature is high but would enable significant strain relaxation between peaks and valleys where curvature is low. It may be advantageous to limit magnitude of the buckling as buckling will lead to local variation in the effective offcut of the crystal surface which may produce spatial variation in growth morphology, strain, and composition that result in broader emission spectra and worse performance. Buckling can be characterized by the ratio of the peak to valley height and the peak-to-peak width of the buckles. A higher ratio requires that the radius of curvature be smaller in the peaks and valley regions.

Buckling can be inhibited by choosing strained layer thicknesses that are relatively thick. For instance, for there to be a positive driving force for buckling, the strain energy relieved through the full volume of the film can be larger than the strain energy introduced by the regions of high curvature in a buckled film. The strain at the peaks and valleys will increase linearly with both an increasing film thickness and a decreasing radius of curvature such that increasing the strained film thickness will result in a reduction in the magnitude of buckling and an increase in the radius of curvature of peaks and valleys.

If buckling does occur, then it is possible the effects of buckling on subsequent growth can be minimized by growing a planarization region. The planarization layer comprises one or more layers of InGaN, GaN, AlGaN, InAlN, or AlInGaN grown under growth conditions that promote formation of a flat surface. Local variations in film crystal orientation due to buckling would be accommodated either as variation in strain at the planar surface or by the presence of microfacets. Growth of a thick planarization layer may enable homogenization of the strain state at the epitaxial surface to reduce the full-width-at-half-maximum of the strain distribution. Changes in growth conditions that may promote planarization include but are not limited to changes in growth temperature, introduction of hydrogen gas, changes in V/III ratio, use of a species such as Ga, In, Al, Mg, or Si as a surfactant with the atomic species introduced to the growth chamber in the form of a metal-organic precursor species or as silane. In some implementations, a strained layer that buckles during relaxation is planarized as follows:
1. First growing a thick, strain-relaxed InGaN, InAlN, or InAlGaN layer.
2. Planarization of the resulting thick layer with a chemical-mechanical polishing process (CMP).
3. Cleaning the polished surface to remove contaminants from the CMP process.
4. Reintroducing the substrate to the growth environment to continue growing strain-relaxed LED device layers.

Strained layers, layers with inhomogeneity, layers that decompose or are altered by a processing operation may be distinct from each other. In some implementations, a first layer grown on a template is not substantially strained, but is prone to alteration by a process operation. For instance, the first layer grown may be an AlInN or AlInGaN layer lattice-matched to a GaN template (e.g., the template region 102). A second, strained (e.g., compressively strain) layer is then grown above the first layer (e.g., the strain-relaxation region 103). The relaxation process (relaxation operation) can then be applied. For instance, this operation can decompose the first layer, forming nano-pores or voids (cavities, etc.) that make it mechanically-compliant. The first layer then deforms to reduce the strain in the second layer. As the first layer is not significantly strained, it may benefit from a low defect density. In some implementations, the misfit strain of the first layer (before the process operation) is less than 1% (or 0.5%, 0.2%, 0.05%, 0.01%). In some implementations, the misfit strain of the second layer (before the process operation) is more than 0.5% (or 1%, 1.5%, 2%, 5%). Inhomogeneities (e.g., in-plane inhomogeneities) can include, as some examples, a plurality of voids (which can also be referred to as cavities, of a plurality of metallic regions. In some implementations, inhomogeneities can take other forms.

Such approaches decouple the properties of the first and second layer. The first layer may have a low strain (lattice matched, or slightly tensile or compressive) beneficial for its growth quality. This may reduce constraints related to its critical thickness. Accordingly, the first layer may be at least 1 nm (or 5 nm, 10 nm, 50 nm, 100 nm) thick. The second layer may have a desired strain level to achieved a desired relaxation level/lattice constant.

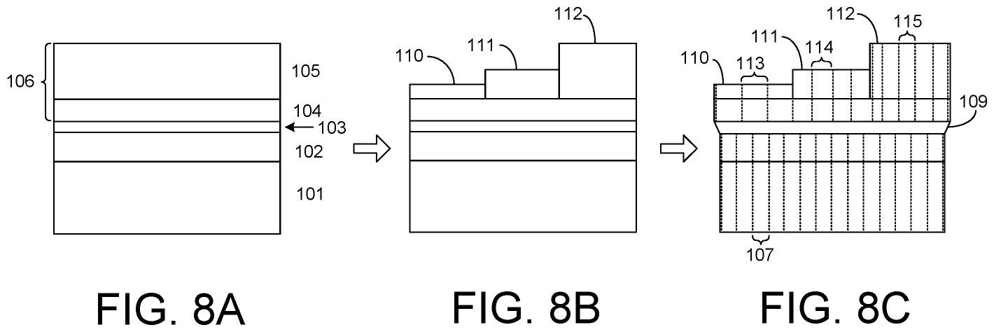

In some implementations, a relaxation-inhibition layer can be patterned prior to performing a relaxation operation or relaxation process to achieve relaxation of an associated base region. For instance, a relaxation-inhibition layer thickness can be varied spatially to produce sub-regions of varying lattice constant on the regrowth surface of the base region. FIGS. 8A to 8C are diagrams schematically illustrating an example process for achieving relaxation of a base region, e.g., of an LED device structure. For instance, FIG. 8A illustrates the example of FIG. 1A, prior to performing a relaxation process. For instance, the example structure of FIG. 8A includes the substrate 101 (e.g., an epitaxial substrate, etc.), the template region 102, the strain-relaxation region 103, and the base region 106, where the base region 106 includes the InGaN layer 104 and the relaxation-inhibition layer 105.

FIG. 8B shows the structure of FIG. 8A, after performing after patterning, to create at least three sub-regions (sub-region 110, sub-region 111, and sub-region 112) using standard lithographic techniques and/or etch processes to selectively thin respective portions of the relaxation-inhibition layer 105 to produce the sub-regions 110, 111, and 112 with different thicknesses. In some implementation, pluralities of each of the sub-regions 110, 111 and 112 can be produced during the patterning shown in FIG. 8B. Because an areal strain energy density of a strained film varies linearly with the film thickness, reducing thickness of the relaxation-inhibition layer thickness 105 for the sub-regions 110, 111 and 112 reduces the areal density of strain energy stored in the relaxation-inhibition layer 105 as the InGaN layer 104 lattice expands. Thin relaxation-inhibition layer regions, such as the sub-region 110, can, therefore, facilitate more relaxation of the InGaN layer 104 than thicker relaxation-inhibition layer regions, such as the sub-region 112.

FIG. 8C illustrates the structure of FIG. 8B shows after relaxation (e.g., with the modified strain-relaxation region 109), with a lattice constant 113 in the sub-region 110 with the thinnest inhibition layer, expanding to a value closest to an equilibrium lattice constant of the InGaN layer 104, and a lattice constant 115 in the sub-region 112 with the thickest inhibition layer, expanding a least of amount of the surface sub-regions 110, 111, and 112.

Using the approaches of FIGS. 8A-8C, e.g., by combining various layers (sub-regions) of various strain states (including InGaN layers, strain-inhibition layers, layers with compressive strain, layers with tensile strain, etc.) and appropriate thicknesses, a desired total strain energy in a layer stack can be achieved and, as a result, facilitate achieving a desired in-plane lattice constant (or, equivalently, a desired relaxation level of a base region) after a relaxation operation.

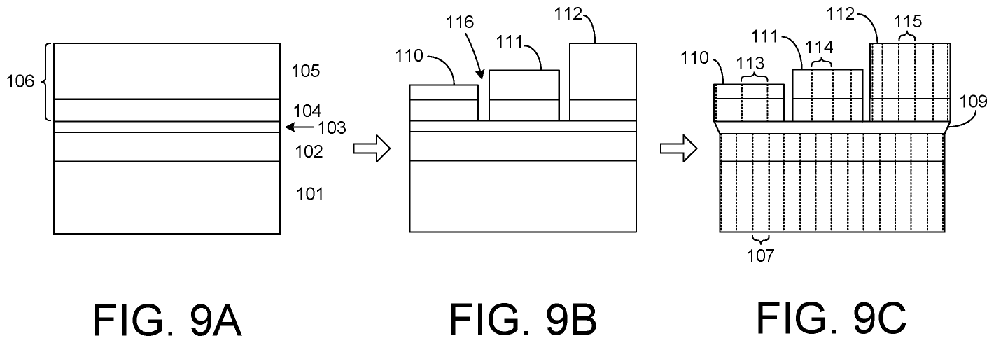

In some implementations, trenches can be formed (etched, etc.) between regions of a patterned relaxation-inhibition layer and result in a corresponding base region having a plurality of mesas of varying heights. FIGS. 9A to 9C are diagrams schematically illustrating an example process for producing a base region having mesas of varying heights, e.g., of an LED device structure. For instance, FIG. 9A illustrates the example of FIG. 1A, prior to defining such mesas. For instance, the example structure of FIG. 9A includes the substrate 101 (e.g., an epitaxial substrate, etc.), the template region 102, the strain-relaxation region 103, and the base region 106, where the base region 106 includes the InGaN layer 104 and the relaxation-inhibition layer 105.

FIG. 9B shows the structure of FIG. 9A, after forming sub-regions 110, 111 and 112, such as in FIG. 8B and forming trenches 116 through the base region 106 and between respective portions of the sub-regions 110, 111, 112, such that portions of the strain-relaxation region 103 are exposed at the bottoms of the trenches 116, and mesas of varying heights are defined from the sub-regions 110, 111 and 112, with their respective lattice constants of 113, 114 and 115. In some implementations, expansion of the mesas of FIG. 9B will result in respective widths of the trenches 116 reducing, or completely closing. In some implementations, the trenches 116 can be etched into the strain-relaxation region 103. In some implementations, the trenches 116 can be etched through the strain-relaxation region 103 and into the template region 102, or the substrate 101. In some implementations, the trenches 116 are used to provide physical access to the strain-relaxation region 103 to enable modification of the strain-relaxation region 103, e.g., by chemically etching the strain-relaxation region 103.

In some implementations, one or more LED devices grown on a template wafer with multiple pluralities of regions (e.g., pluralities of the sub-regions 110, 111 and 112) with different lattice constants is optimally grown on a layer whose lattice constant equal to that of the template region 102. In some implementations, methods, such as those described herein, can be performed to ensure that one or more of regrowth surfaces have a same lattice constant as an associated template region, e.g., the template region 102.

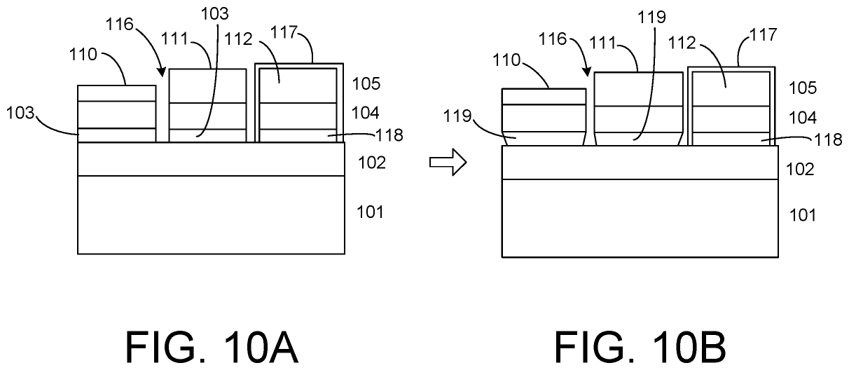

In some implementations, e.g., where modification of a strain-relaxation region is achieved using a chemical process, and a plurality of mesa are formed from a corresponding base region by etching a pattern of trenches into the base region (e.g., FIG. 9B), relaxation of one or more of the mesas can be inhibited by encapsulation of one or more base region mesas with a material that prevents an associated etch chemistry from accessing the relaxation region of the one or more encapsulated mesas. FIG. 10A is a diagram that illustrates a device structure wafer where the base region and relaxation region have been patterned into a plurality of mesas by the etching of trenches in the base and relaxation regions, such as the structure of FIG. 9B. In the example of FIG. 10A, a mesa defined from the sub-region 112 is encapsulated, or covered by a passivating material 117, such that a respective portion of a strain-relaxation region 118 associated with the encapsulated mesa is also covered by the passivating material, such that that portion of the strain-relaxation region 103 is not accessible by liquids and/or gasses used in modifying the strain-relaxation region 103 to promote strain relaxation of the base region (e.g., the base region 106).

FIG. 10B is a diagram schematically illustrating a relaxed template with three base region mesas formed, respectively, from the sub-regions 110, 112 and 112 of the structure of FIG. 8B, with the mesas having different strain states. For instance, mesa regions associated with the sub-regions 110 and 111, in this example, have strain states determined by respective thicknesses and compositions of corresponding relaxation-inhibition layers and modified strain-relaxation regions 119 that were modified by a chemical process to promote relaxation of the baser regions. In this example, the mesa region associated with the sub-region 112 remains pseudomorphic to the template region 102 due to the strain-relaxation region 103 remaining unmodified due to its encapsulation with the passivating material 117.

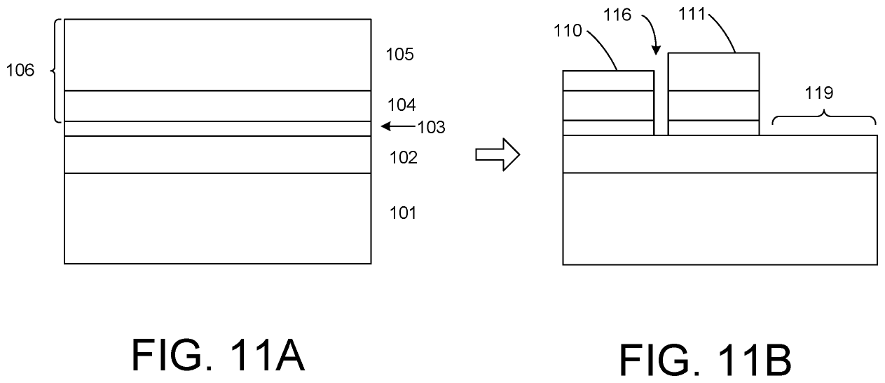

In some implementations, a base region, such as those described herein, can be processed to define a plurality of mesas by etching a pattern of trenches patterned in the base region, where one or more of the base region mesas (e.g., one or more respective, entire sub-regions) are removed to expose the template region. In such implementations, using the exposed surface of an associated template region as a regrowth surface can ensure at least one of the mesa regions has a same lattice constant as the template region. As with FIGS. 8A and 9A, FIG. 11A illustrates the example of FIG. 1A, prior to performing a relaxation process. For instance, the example structure of FIG. 11A includes the substrate 101 (e.g., an epitaxial substrate, etc.), the template region 102, the strain-relaxation region 103, and the base region 106, where the base region 106 includes the InGaN layer 104 and the relaxation-inhibition layer 105.

FIG. 11B is a diagram schematically illustrating the structure of FIG. 11A, where sub-regions 110 and 111 are grown pseudomorphic to the template region and corresponding mesas are defined from the sub-regions 110 and 111. In this example, these mesas will relax when the strain-relaxation region 103 is modified to have lattice constants determined by a thickness and composition of the relaxation inhibition regions, e.g., defined from the relaxation-inhibition layer 105. Also, in the example of FIG. 11B, a mesa associated with sub-region 112 (e.g., of the structure of FIG. 9B) is etched away to form a region 119 where a regrowth surface includes an exposed portion of the template region 102. Regrowth of LED structures can then be performed on the top of the sub-region 110 (e.g., mesa), on the top of sub-region 111 (e.g., mesa), and on the top of the region 119.

In some implementations, the base region 106 or a portion thereof is doped (e.g., n-doped or p-doped). For instance, the base region 106 has an n-doped InGaN region due to the presence of one or more dopants (such as O, Si) or a p-doped InGaN region due to the presence of a dopant (such as Mg, Ge). The doping level may be sufficient to provide good carrier conductivity: it may be at least 1E16 (e.g., 5E16 or more, 1E17 or more, 5E17 or more, 1E18 or more, 5E18 or more, 1E19 or more, 5E19 or more). The doping level may be low enough to avoid free-carrier absorption. For instance, the doping level may be less than 1E20 (e.g., 5E19 or less, 1E19 or less, 5E18 or less, 1E18 or less). Suitable lower and upper doping bounds may depend on the doping species (due to variations in activation level and optical cross-section among species). In some implementations, the doping species is 0 and the doping level is in a range 1E17-1E19 cm⁻³. The doping species may form a variety of states in the crystal, including complexes and interstitials. Implementations where the base region is p-doped open the possibility for reverse-polarity structures (i.e., junctions with n over p in the LED stack). In such cases, LED growth (e.g., regrowth) may begin with undoped InGaN, growth of undoped layers including the active region, and finally growth of n-GaN. If needed, the base region 106 may be activated before regrowth. Reverse-polarity structures may be inverted during processing to expose the p-layers of the base region; a p-regrowth operation may be performed on these exposed p-layers to create a contact layer for forming a p-contact.

In some implementations, the base region 106 growth conditions are selected to reduce defect formation. In particular, low density of vacancies (including N or Ga or In) may be sought, with a density of a vacancy less than 1E18 cm⁻³ (e.g., 1E17 cm⁻³ or less, 1E16 cm⁻³ or less, 1E15 cm⁻³ or less, 1E14 cm⁻³ or less, 1E13 cm⁻³ or less, 1E12 cm⁻³ or less, 1E11 cm⁻³ or less, such as 1E10 cm⁻³). The low density may be achieved by employing a relatively low growth temperature, such as 900° C. or less (e.g., 850° C. or less, 800° C. or less, 750° C. or less, 700° C. or less, 650° C. or less, 600° C. or less, 550° C. or less, 500° C. or less). The low density may be achieved by employing high partial pressure of the corresponding species.

The composition of the base region 106 may be controlled to limit optical absorption of the light emitted by the LED region. In some implementations, the LED region has sub-regions emitting at various wavelengths (e.g., blue/green/red), hence, reabsorption of the shortest wavelength is the likeliest. The composition of the base region 106 can be selected to limit optical absorption of the shortest wavelength. In some implementations, a sub-region of the LED region emits short-wavelength light (e.g., blue light) with a peak wavelength, and the bulk absorption coefficient of the base region at the peak wavelength (e.g., the absorption it would have in bulk form) is less than 10 cm⁻¹ (e.g., 5 cm⁻¹ or less, 2 cm⁻¹ or less, 1 cm⁻¹ or less). In some implementations, after a full device is formed, the net power absorption of short-wavelength light by the base region is less than 10% (e.g., 5% or less, 2% or less, 1% or less). This net power absorption quantifies how much of a total amount of light is absorbed by the base region 106, and competes directly with a given device's net extraction efficiency. In other words, the extraction efficiency (for a subpixel of given color) can be written Cₑₓ=1−A_{base}−Aₒₜₕₑᵣ, with A_{base} being the net base region absorption and A other being the absorption from other (e.g., all other) sources (metal, active region, free carrier absorption . . . ). In some implementations, A_{base}<10% (e.g., <5%, <2%, <1%) for blue subpixels.

Absorption may be reduced by selecting a composition and thickness of absorbing materials, such as described herein. Other approaches can be used to limit absorption, alone or together with material composition. This includes forming LED devices where light trajectories between subpixels (e.g., from a blue LED to a red LED) are reduced or blocked, for instance by forming an optical-isolation layer (e.g., a reflector, a mirror, etc.) between subpixels. This can include selecting an appropriate physical layout for subpixels. This can include removing an absorbing material (e.g., by etching, grinding, and other techniques disclosed herein). In some implementations, an absorbing material (e.g., a substrate, an epitaxial layer, a portion of a base material) is present during some epitaxial operations and is removed, or partially removed (e.g., at least 25%, at least 50%, at least 90% of the material is removed) while devices are processed (formed, produced, etc.).

Accordingly, an In composition of the base region 106 may be high enough to reduce the strain in the active region but low enough to reduce optical absorption. In some implementations, an In composition of the base region 106 is in a range of 2%-20% (e.g., 5-10%, 2-5%, 3-10%, 5-8%, 5-12%, 5-15%, 10-20%).

In some implementations, the regrowth region (e.g., the surface of the sub-region 110, or the sub-region 111 or the region 119 in FIG. 11B) is prepared for regrowth. A surface treatment may be performed to ensure the regrowth region is epi-ready. The surface treatment may include one or more wet etches (including acid, base, solvent). Some wet etches may selectively etch some crystal planes. Wet etches may comprise KOH or H₃PO₄ etch. In some implementations, a polishing operation is performed to obtain a smooth surface, with an RMS roughness less than 5 nm (e.g., 3 nm or less, 1 nm or less, 5 Å or less, 3 Å or less). The polishing may be mechanical, chemical, chemical-mechanical, grinding, and/or other techniques. In some implementations, a dry etch operation (such as ICP, RIE) is used to etch material. Several techniques may be combined to achieve a desired thickness and a desired surface state. In some implementations a first operation (e.g., a dry etch) removes material, and a second operation (e.g., polishing or wet etch) facilitates a low roughness. In some implementations, the regrowth region has a surface with a desired offcut from a crystal direction. For instance, the regrowth surface may be slightly off from a c-plane, with an offcut angle in a range 0.1-5° (e.g., 0.1-1° or 1-5°) in a specific direction (including the a-plane or m-plane). The offcut may be obtained by a polishing operation.

A growth reactor used to perform various operations described herein can be operating at a pressure selected for high material quality and desired material properties. A high pressure may be desirable to reduce the presence of some defects, including vacancies. In some implementations the pressure is atmospheric pressure, or is higher than 1 atm (such as at least 1.2 atm, at least 1.5 atm, at least 2 atm, at least 5 atm, at least 10 atm). In some implementations, the partial pressure of the N-containing species is high to reduce the presence of N-vacancies in the crystal. In some implementations, the pressure is selected to promote strain relaxation as disclosed herein.

For instance, a metal-organic chemical vapor deposition (MOCVD) reactor may adopt a variety of geometries, including geometries more often encountered in other growth techniques, which may provide certain advantages for some implementations. For instance, an MOCVD reactor may have a longitudinal/horizontal shape. It may have a vertical flow. The reactor may be a dual-flow reactor, with a carrier gas flow in a given direction and a secondary gas flow in a second direction that facilitates control of the carrier gas flow. It may have a showerhead design. It may be of horizontal flow design with multiple flow streams separating the metal-organic species from the reactive nitrogen species (e.g., ammonia). The geometry may be selected to improve growth uniformity. The growth may occur over at least one wafer with a radius of at least 4 inches, and the In composition of the base region material may vary by less than 3% (e.g., 2% or less, 1% or less, 0.5% or less) across an area which is at least 60% (e.g., 80% or more, 90% or more) of the wafer area. The reactor material may include quartz, graphite, SiC, sapphire, steel, tungsten and molybdenum. It may be a cold-wall reactor. It may be a hot-wall reactor, with the temperature of the inner walls of the reactors maintained above a desired temperature, including at least 400° C. (e.g., 500° C. or more, 600° C. or more, 650° C. or more, 700° C. or more). The reactor may be designed to limit the presence of specific atomic species in the crystal. This includes species including Fe, Cu, Sn, C, B, Mn, etc. Concentration of a selected species may be below 1E15 cm⁻³ (e.g., 1E14 cm⁻³ or less, 1E13 cm⁻³ or less, 1E12 cm⁻³ or less, 1E11 cm⁻³ or less, 1E10 cm⁻³ or less). In some implementations, the part of the reactor where growth occurs is set at a higher temperature than other parts of the reactor, to reduce defect incorporation and/or parasitic nucleation. The temperature difference may be at least 50° C. (e.g., 100° C. or more, 150° C. or more). In some implementations, a wafer temperature may be kept below an upper threshold temperature to limit the formation of some defects with high formation energy (e.g., N-vacancies and/or group III-vacancies) in a base material. Accordingly, the wafer temperature may be in a range 400-1000° C. (e.g., 500-600° C., 400-800° C., 450-750° C., 550-650° C.).

In some implementations, a molecular beam epitaxy (MBE) reactor may be used to grow the LED device layers. Reactive nitrogen species may be provided by means of a nitrogen plasma source or injection of reactive, nitrogen-bearing species such as ammonia, hydrazine, and the like.

The base region 106 may be processed before an LED region is grown. The base region 106 may be transferred to a sub-mount before the LED region is grown. In some cases, the base region 106 has a planar top surface. The top surface may have group-III polarity (i.e., along the +c direction). It is transferred once, with the top surface attached to the sub-mount. The growth substrate and buffer (if any) may be removed by techniques described herein, including grind and polish, and/or laser lift off. A portion of the exposed base region 106 may be removed/thinned down; this may include a non-coalesced portion (e.g., a portion with the lateral structures). This can be achieved by techniques disclosed herein, including grind and polish. The base region after this operation may be planar (e.g., substantially planar within processing limits).

In some implementations, the base region 106 may be transferred a second time to a second sub-mount. After this, the base region 106 may be a planar layer continuously attached to the second sub-mount, with the top surface exposed again. The transferred base region 106 may be used as a growth substrate/template for LED growth (regrowth). The transferred base region 106 may further be patterned (e.g., with mesa shapes): mesas with small dimensions may be formed, such as micron-scale mesas suitable as sub-pixels. Such mesas may be formed at various parts of the process, for instance once the base region is thinned on the first sub-mount, or after the base region is transferred to a second sub-mount.

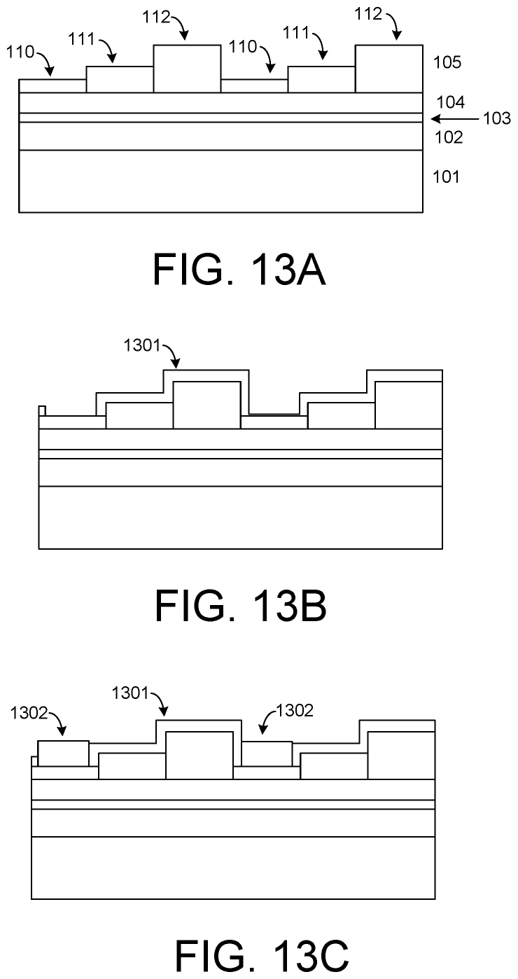

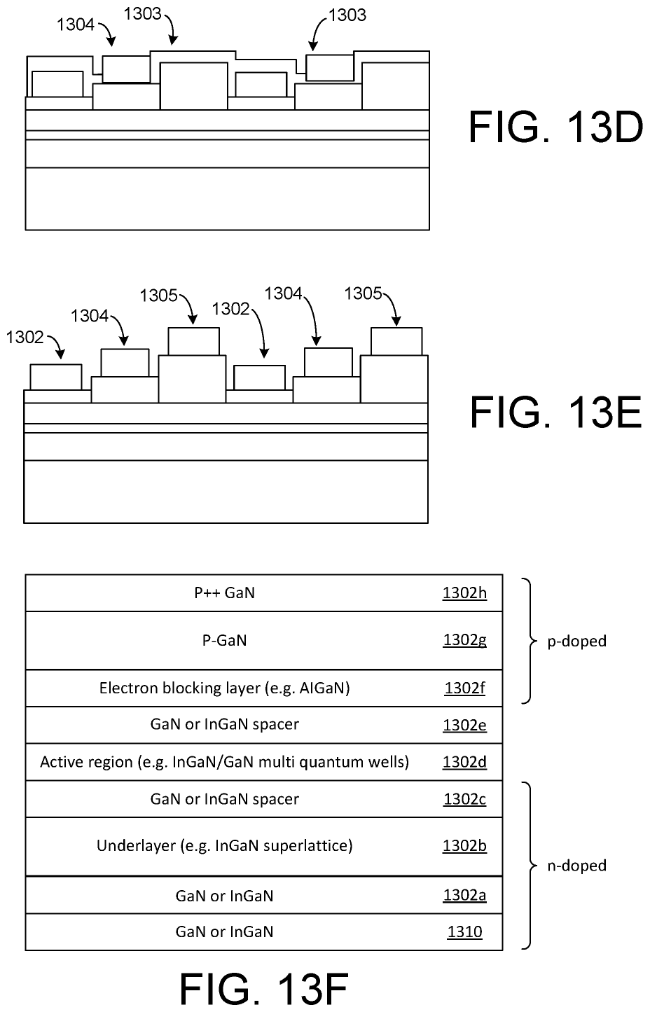

An LED region can be grown (regrown) on a regrowth surface of a base region (e.g., the base region 106). For instance, referring to FIGS. 8A to 10B, regrowth may occur on surfaces (e.g., upper surfaces) of sub-regions 110, 111, 112. Referring to FIGS. 11A-11B, regrowth may occur on the surface of the sub-regions 110, the sub-regions 111, and/or the region 119. Regrown LEDs, and an associated method of producing regrown LEDs, are illustrated in FIGS. 13A-13F. For example, LEDs 1302 are respectively regrown on the sub-regions 110; LEDs 1304 are respectively regrown on the sub-regions 111; and LEDs 1305 are respectively regrown on the sub-regions 112.

FIG. 13F, which is described in further detail below, schematically illustrates a non-limiting example of an epitaxial layer stack of a regrown LED. Again, the LED stack of FIG. 13F can be regrown on a regrowth interface, e.g., the surfaces of the sub-regions 110, 111 or 112, and/or the region 119. As shown in FIG. 13F, and discussed below, the example epitaxial layer stack includes n-doped layers, p-doped layers, and an active region at a p-n junction.

The LED region may have InGaN layers (doped and/or undoped) for carrier transport, akin to the GaN n-layers, p-layers, and lower and upper barriers used to implement III-nitride LEDs. It may have AlGaN or AlInGaN or AlInN layers which serve the role of an electron blocking layer. It may have an active region with light-emitting quantum wells (QWs)/barriers made of InGaN/GaN or InGaN/InGaN. It may have a defect-reduction layer (such as a homogeneous InGaN or AlInN layer, or a superlattice of InGaN/InGaN, InGaN/GaN, InGaN/AlInN and other variations of III-nitride layers). These various layers may have a composition selected to reduce strain of the light-emitting layers.

In some implementations, the LED region is pseudomorphic with the regrowth surface, or it is close to pseudomorphic (with every layer in the LED region having an in-plane lattice constant which differs from that of the regrowth surface by less than 0.1% or 0.01%). Therefore, controlling the lattice constant of the regrowth surface can be desirable, as it can determine the strain state of the active region.

In some implementations, the active region includes one or more QWs having a composition. The composition may include at least 10% (e.g., 15% or more, 20% or more, 25% or more, 30% or more, 35% or more, 40% or more) In.

The base region and layers of the LED region may be configured to reduce strain of the QWs. For instance, the base region can have a base composition (e.g., In0.1GaN [indicating 10% of In atoms and 90% of Ga atoms in the layer]), and some p-layers and p-layers of the LED region can have the same base composition, so that they are strain-free. Barriers between QWs may also have the same base composition, or a similar composition. The composition of barriers may be configured to compensate for stress of the QWs. For instance, the barriers have less In than the base region, and they can be in tensile strain, which compensates the compressive strain of the QWs.

An example of compositions of layers in an example layer stack is illustrate in Table 1 (with one or more (e.g., all) layers but the first (e.g., Base) being regrown as part of as LED region):

TABLE 1

| Name | Composition | Thickness | | Strain state |
|---|---|---|---|---|
| Base | In0.1GaN | 0.1 um-1 um | | Relaxed |
| n-layer | In0.1GaN | 100 | nm | Relaxed |
| Defect-reduction layer | In0.1GaN/ | 100 | nm | Relaxed/ |
| (n-doped) | In0.15GaN | | | compressive |
| | superlattice | | | |
| Spacer (n-doped and/or | In0.1GaN | 10 | nm | Relaxed |
| undoped) | | | | |
| QW | In0.3GaN | 2.5 | nm | Compressive |
| Barrier | In0.05GaN | 5 | nm | Tensile |
| QW | In0.3GaN | 2.5 | nm | Compressive |
| Barrier | In0.05GaN | 5 | nm | Tensile |
| QW | In0.3GaN | 2.5 | nm | Compressive |
| Spacer (p-doped and/or | In0.1GaN | 10 | nm | Relaxed |
| undoped) | | | | |
| Electron blocking layer | GaN | 20 | nm | Tensile |
| (p-doped or undoped) | | | | |
| p-layer | In0.1GaN | 100 | nm | Relaxed |
| p++ layer | In0.1GaN | 20 | nm | Relaxed |

Strain state can be quantified by various quantities. For instance, a convenient quantity is misfit strain (or basal strain field) between the in-plane lattice parameters of two layers:

e=(a_b−a_1)/a_1,

where a_b is an equilibrium in-plane lattice constant of the base region (i.e., the region on which pseudomorphic growth occurs) and a_1 is an in-plane equilibrium lattice constant of the layer being grown.

In some implementations, the misfit strain in the QWs is reduced to less than 80% (e.g., 50% or less, 30% or less, 20% or less, 10% or less) of the misfit strain if the QWs were grown pseudomorphically on a relaxed GaN surface. For instance, c-plane In20GaN QWs grown pseudomorphically on c-plane GaN would have a misfit strain value of −2.2%. In some implementations, the same In20GaN QW is grown pseudomorphically on a relaxed In10GaN layer, and its misfit strain is about −1.1%, which is about half the strain for growth on GaN.

Table 2 below illustrates example implementations. Implementations shown n Table 2 may be configured according to lower and upper bounds shown in Table 2. For instance, an implementation may have a base region with an in-plane lattice constant having a value above a selected value (e.g., 3.22 A) and an active region having at least an InGaN composition above a selected value (e.g., 30%), and be configured to have a misfit strain ratio below a selected value (e.g., 67%). In Table 2, the base region equivalent In % is the approximate indium content of an InGaN film with an equilibrium lattice constant equal to the listed base region in-plane lattice constant.

TABLE 2

| Base | | | | | |
|---|---|---|---|---|---|
| region | Base region in- | Active | Active layer in- | | Misfit |
| equivalent | plane lattice | layer | plane lattice | Misfit | strain |
| In % | constant [nm] | In % | constant [nm] | strain | ratio |
| 5% | 0.32068 | 20% | 0.32602 | −1.6% | 75% |
| 5% | 0.32068 | 30% | 0.32958 | −2.7% | 83% |
| 5% | 0.32068 | 40% | 0.33314 | −3.7% | 88% |
| 5% | 0.32068 | 50% | 0.3367 | −4.8% | 90% |
| 10% | 0.32246 | 20% | 0.32602 | −1.1% | 50% |
| 10% | 0.32246 | 30% | 0.32958 | −2.2% | 67% |
| 10% | 0.32246 | 40% | 0.33314 | −3.2% | 75% |
| 10% | 0.32246 | 50% | 0.3367 | −4.2% | 80% |
| 15% | 0.32424 | 20% | 0.32602 | −0.5% | 25% |
| 15% | 0.32424 | 30% | 0.32958 | −1.6% | 50% |
| 15% | 0.32424 | 40% | 0.33314 | −2.7% | 63% |
| 15% | 0.32424 | 50% | 0.3367 | −3.7% | 70% |
| 20% | 0.32602 | 30% | 0.32958 | −1.1% | 33% |
| 20% | 0.32602 | 40% | 0.33314 | −2.1% | 50% |
| 20% | 0.32602 | 50% | 0.3367 | −3.2% | 60% |
| 20% | 0.32602 | 60% | 0.34026 | −4.2% | 67% |
| 25% | 0.3278 | 30% | 0.32958 | −0.5% | 17% |
| 25% | 0.3278 | 40% | 0.33314 | −1.6% | 37% |
| 25% | 0.3278 | 50% | 0.3367 | −2.6% | 50% |
| 25% | 0.3278 | 60% | 0.34026 | −3.7% | 58% |

In the examples of Table 2, it is assumed that the base region is relaxed InGaN. However, other materials with a similar in-plane lattice constant (including In-containing III-nitride compounds and other materials) are also suitable. The misfit strain ratio is the ratio of the actual misfit strain (between the base region and active layer) to the value of the misfit strain if the active layer were grown pseudomorphically on GaN.

In some implementations, the strain component epsilon_3 is approximately proportional to the misfit strain, and the strain-induced polarization field is therefore approximately proportional to the misfit strain. Accordingly, the misfit strain ratio values enabled herein may also correspond to values of the polarization field ratio, which is defined as the actual polarization field in an active layer divided by the polarization field if the structure were pseudomorphically to GaN.

In some implementations, at least 50% (e.g., 80% or more, 90% or more) of the light emitted by an LED is emitter by one or several active layers, and the active layers can be further characterized by properties described herein (such as composition, misfit strain, misfit strain ratio, polarization field ratio, etc.).

In some implementations, the active region has a composition, and a thickness which is at least 1.5× (e.g., 2× or more, 3× or more) the critical thickness for pseudomorphic growth on relaxed GaN at that composition. This is facilitated by the strain reduction in the active region. In some implementations, a QW has a thickness in a range 2-4 nm and a composition in a range 30-60%.

In some implementations, the active region has a light-emitting layer with In content of at least 30% (e.g., 35% or more, 40% or more, 50% or more, e.g., in a range 30-60%), and a thickness of at least 2 nm (e.g., 2.5 nm or more, e.g., in a range 2-5 nm).

In implementations, such as those described herein, maintaining a low defectivity and/or a high IQE can be achieved while also reducing active region strain. This is facilitated by LED growth on a relaxed base region.

Accordingly, some implementations are characterized by a low defect level in the active region. The active region may have a TDD less than 5E8 cm⁻² (e.g., 1E8 cm⁻² or less, 5E7 cm⁻² or less, 1E8 cm⁻² or less, 5E6 cm⁻² or less, 1E6 cm⁻² or less). It may have a density of stacking faults or misfit dislocations less than 1E5 cm⁻¹ (e.g., 1E4 cm⁻¹ or less, 1E3 cm⁻¹ or less, 1E2 cm⁻¹ or less, 1E1 cm⁻¹ or less). In implementations having lateral structures, the density of defects (including TDDs, stacking faults, v-pits) may be less than 500 per lateral structure (e.g., 250 or less, 100 or less, 50 or less, 10 or less).

Regrowth interfaces are known to be sources of point defects. Extrinsic point defects such as dopant or foreign species can accumulate on the sample surface during exposure to the environment or processing operations carried out between the end of the template growth and the regrowth of LED layers. In implementations where a template wafer is removed from the growth reactor for processing or modification of the relaxation region prior to any of the one or more LED regrowth operations, the regrowth surface may be prepared prior to regrowth to limit or eliminate the introduction of defects during the LED growth operation. Regrowth surface preparation operations may include cleaning with solvents (e.g. acetone, isopropyl alcohol, methanol, and the like) to remove hydrocarbons, cleaning with acids and acidic solutions (e.g. HF or buffered HF solutions, HCl, nitric acid, sulfuric acid, piranha etch, HF/peroxide mixtures, aqua regia, and the like) to remove foreign metallic species and oxides, cleaning with ultraviolet light and ozone-based cleaning processes to remove hydrocarbons, cleaning with oxygen-based plasmas to remove hydrocarbons, cleaning or etching with fluorine or chlorine-based plasmas to remove surface oxides, etching of nitride materials with acids or bases (e.g. KOH, NaOH, phosphoric acid) or other selective etches of group-III nitride materials to remove damaged layers of nitride materials at the regrowth surface, photochemical or photo-electrochemical etching of group-III nitride materials to remove damaged layers of nitride materials at the regrowth surface.

Some implementations are characterized by a high internal quantum efficiency (IQE). The high IQE may be substantially higher than what could be obtained by conventional strained growth on GaN. This may be facilitated by the reduced strain in the active region.

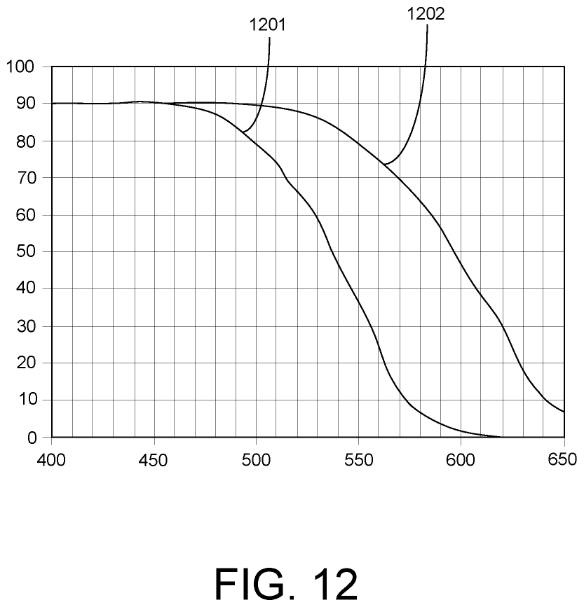

FIG. 12 is a graph illustrating a relationship between wavelength and IQE, and contrasts a prior implementation (trace 1201) with an implementations in accordance with the approaches described herein (trace 1202). As shown by the trace 1201, IQE (y-axis) of prior implementations is significantly reduced at longer wavelengths (x-axis), which is a manifestation of well-known green gap. Strain can contribute, at least in part, to this reduction in IQE. Accordingly, impact of strain on IQE can be modeled, and improvement in IQE of a LED device a result of strain reduction can be predicted. As shown by the trace 1202 (e.g., for astrain reduced structures) demonstrates the benefit of the approaches described herein.

For this example, a fully-relaxed base region with In0.05GaN was considered. Prior implementations, for red light emission (e.g., with a wavelength between 620 nm and 630 nm) have an EQE of about 2-2.5%, corresponding to an IQE of about 3%. In contrast, implementations described can have an IQE of at least 5% (e.g., 10% or more, 15% or more, 20% or more, 30% or more) at a peak emission wavelength of at least 610 nm (e.g., 620 nm or more, 625 nm or more, 630 nm or more). FIG. 12 and the associated examples are provided for purposes of illustration, and other values of In composition and strain relaxation, compared to the values used in this example, may be required to achieve a desired IQE. Implementations include methods of selecting a desired peak emission wavelength and at least one criterion for a figure of merit of an optoelectronic device (including a minimum desired value of IQE or external quantum efficiency (EQE) or wall plug efficiency (WPE)), and configuring an emitter as taught herein (including selecting a composition and a strain state for a base region) to achieve the at least one criterion. In one implementation, the emission wavelength is at least 615 nm, the IQE is at least 15%, and the base region has an In composition of at least 5% and is substantially fully relaxed.

In some implementations, the base region has a plurality of sub-regions, such as sub-regions 110, 111, 112. The sub-regions have base layers with different In compositions. This can be achieved as disclosed herein (for instance following the process of FIGS. 8A-8C). For instance, there are sub-regions with lattice constant equivalent to fully-relaxed GaN, fully-relaxed In0.05GaN, and fully-relaxed In0.1GaN. The regions with larger lattice constants are more amenable to growing long-wavelength LEDs. Due to the lattice pulling effect, the regions with larger lattice constants may naturally incorporate more In during the LED growth, for the same growth conditions. In some implementations, growth of the LED region occurs simultaneously on the various sub-regions; due to lattice pulling, the various sub-regions have different active region compositions and different emission wavelengths. In some implementations, three sets of sub-regions are present and LEDs are grown simultaneously on these which respectively emit blue, green and red light. The base region may have three sets of sub-regions with different compositions. LED regions emitting blue, green and red light are respectively regrown on the three sets of sub-regions.

In some implementations, re-growth of the LED regions over the several sub-regions (e.g., sub-regions 110, 111, 112) is performed with the same regrowth operation. In other implementations, several regrowth operations are performed. For instance, the base region has 3 sets of sub-regions (e.g., sub-regions 110, 111, 112). A first set of sub-regions (110) is exposed, while the two other sets are covered by a growth mask. The mask may include an oxide material (including SiOx, AlOx); a nitride material (SiNx, AlNx); a dielectric layer; a metal (including W and Mo). A growth operation is performed (e.g., by MOCVD) and LED regions with a first wavelength are formed over the first set of sub-regions—these may form e.g., blue subpixels. The process is repeated for the other two sets of sub-regions (111, 112) to form other LED regions emitting at other wavelengths (e.g., green and red).

FIGS. 13A-13E illustrate a process with regrowth of LED regions, while FIG. 13F, as was indicated above, schematically illustrates an example epitaxial layer stack, which can be used to implement LED active regions (e.g., LED sub-regions 1302, 1304, 1305) as described herein. In this example, as illustrated in FIG. 13A, the process begins with a relaxed template, e.g., as in the example of FIG. 8B, that includes three sets of sub-regions 110, 111, and 112, e.g., of a base region (base region 106). As shown in FIG. 13A, the sub-regions 110, 111 and 112 include relaxation-inhibition layers 105 and at least one InGaN layer 104. In this example, the sub-regions overlay a strain-relaxation region 103, a template region 102, and a substrate 101 (e.g., a semiconductor wafer, an epitaxial substrate, etc.), where the strain-relaxation region 103 has been modified to enable relaxation of the sub-regions 110, 111, and 112. The sub-regions 110, 111, and 112 can have respective lattice constants, such as described herein. Referring to FIG. 13B, a first growth mask 1301 is formed over sub-regions 111 and 112. As shown in FIG. 13C, growth (regrowth) of LED sub-regions 1302 is then performed over the sub-regions 110 using the first growth mask 1301 as a regrowth template. FIG. 13D illustrates removal of the first growth mask 1301 and formation of a second growth mask 1303 over sub-regions 110 and 112. In this example, after repeating masking and epi operations several times, LED sub-regions 1302, 1304, and 1305 are grown on one or more (e.g., all) base of the sub-regions 110, 111, and 112, as shown in FIG. 13E.

In some implementations, the growth mask overlays a portion or all of the top surface of the base sub-regions, as shown in FIG. 13B. In some implementations the growth mask overlays exposed sidewalls of the base sub-regions. In some implementations, where the base region has been patterned into mesas, the growth mask overlays the exposed mesa sidewalls and may partially or fully cover the bottom of the etched trenches, as shown in FIG. 13D.

As shown in FIGS. 13D and 13E, the LED sub-regions 1302, 1304 and 1305 are formed on regrowth regions (e.g., comprising GaN or InGaN), where upper surfaces of the sub-regions 110, 111, and 112 provide a regrowth interface. As described herein, the regrowth regions (e.g., sub-regions 110, 111, and 112) may be relaxed. As shown in FIG. 13F, in this example, a first epitaxial layer 1302a of an LED structure (e.g., a GaN or InGaN layer) is grown on the growth interface (e.g., a regrowth region 1310). In some implementations, the first epitaxial layer 1302a may be pseudomorphic with the regrowth region 1310.

As shown in FIG. 13F, in this example, the following layers can then be grown (e.g., epitaxially grown, in sequence, on the first epitaxial layer 1302a). In the example of FIG. 13F, the layers (regions) grown on the first epitaxial layer 1302a include an underlayer 1302b for defect reduction; a spacer layer 1302c (GaN or InGaN), an active region 1302d (e.g., including InGaN quantum wells); a spacer layer 1302e (e.g., GaN or InGaN), an electron blocking layer 1302f (e.g., an AlGaN layer), a p layer 1302g (e.g., a P-GaN layer), and a p++ layer 1302h (e.g. a highly doped p layer for forming a good (ohmic) contact with low contact resistance). In some examples, all the layers 1302a to 1302h are pseudomorphic with the regrowth region. Although FIG. 13F shows the various layers of the example LED region as planar, in some implementations, such layers may have a variety of geometries, e.g., one or more the layers can be conformal layers that are formed on the top and/or sidewalls of a mesa. In the example of FIG. 13F, materials, such as GaN, InGaN, AlGaN, are provided by way of example and for purposes illustration. In some implementations, other materials can be used for each of the illustrated layers (regions) in FIG. 13F.

In some implementations, successive regrowth operations are performed for different wavelengths, and the regrowth operations for longer-wavelength devices are performed last. For instance, in some implementations, red LEDs are grown last. This may facilitate good material quality, because long-wavelength active regions require high In content, which can have a low thermal budget. In some implementations, one regrowth operation yields red LEDs; this regrowth operation is performed with a low thermal budget. The low thermal budget may be defined by a maximum temperature Tm, with each sub-operation in the operation performed below Tm. Tm may be 900° C. or less (e.g., 850° C. or less, 800° C. or less, 750° C. or less, 700° C. or less, 650° C. or less, 600° C. or less, 550° C. or less, 500° C. or less). The low thermal budget may be defined by a maximum temperature Tm and a maximum time tm, with each sub-operation in the operation performed below Tm, and operations performed at or near Tm lasting less than tm.

In some implementations, the LED region (or layers thereof) is grown with a pulsed growth technique, for instance, by flowing different group-III precursors (such as TMG and TMI) at different times. This may facilitate growth of high-In-content layers.

In some implementations, LED regrowth occurs on the whole free (exposed) surface of the base sub-region or mesa.

In contrast, in some implementations, LED growth only occurs on some parts of the base region—for instance, only on the top surface as shown in FIGS. 8A-8C.

Various techniques, including but not limited to selective area growth (SAG) using a growth mask, may be employed to achieve this top-only growth. The growth parameters may be selected to promote nucleation on the top surface. For instance, the top surface can be a c-plane and the growth conditions promote c-plane nucleation against other planes (e.g., m-plane, c-plane, semi-polar planes). Suitable growth conditions may include temperature, pressure, partial pressure of various precursors, III/V ratio, growth rate, use of pulsed growth. In some implementations, a low temperature is employed to promote top surface growth. The temperature for growing a light-emitting layer may be less than 800° C. (e.g., 775° C. or less, 750° C. or less, 725° C. or less, 700° C. or less, 650° C. or less, 600° C. or less). A growth technique suited for low temperature growth may be employed (including MBE, sputtering, plasma-assisted CVD, and other CVD techniques suited for low temperature).

Sidewalls may be covered to prevent epi growth (regrowth) on the sidewalls. In some implementations, a dielectric material (e.g., SiOx, AlOx, SiNx, AlNx, TiOx, TaOx, ZrOx) is deposited on the sidewalls to prevent epi regrowth.

As described herein, a regrowth surface may be prepared for regrowth (e.g., to be epi-ready). Such preparation operations may occur before or after the dielectric coating operations described here.

In some implementations, layers of an LED region are configured to achieve specific polarization fields and control the overlap of electron and hole wavefunctions (WF) in the light-emitting layers. For various crystal directions, III-nitride heterostructures display polarization fields, both spontaneous and strain-induced. The fields have various effects, including separation of the WF overlap (which may be detrimental to radiative efficiency), increase of the emission wavelength (which may be beneficial, especially to reach a longer wavelength with a given material composition). Accordingly, implementations may seek a field with a given strength, or in a given range, to mitigate the trade-off between these effects. In some implementations, the magnitude of polarization fields in the active region is reduced thanks to the reduction in strain (for instance, an In0.3GaN QW has a lower polarization field when pseudomorphic to an In0.1GaN base region than when pseudomorphic to a conventional GaN layer). In some implementations, layers around the active region are selected to manipulate the strain difference and therefore the field. For instance, the active region may include an In(x)Ga(1-x)N light-emitting QW, and at least one layer next to the QW (e.g., a barrier) which includes In(y)Ga(1-y)N with y<x, or GaN, or AlGaN, or AlInGaN. In some implementations, the barriers between QWs are composed of multiple layer. For instance, the stack between two QWs may be (with either the p- or the n-side being on the left), such as illustrated by the following example stack arrangements:
InGaN QW/InGaN/InGaN/InGaN QW
InGaN QW/InGaN/GaN/InGaN QW
InGaN QW/InGaN/AlGaN/InGaN QW
InGaN QW/GaN/AlGaN/InGaN QW

In some implementations, a QW has a polarization field in a range 1-4 MVcm⁻¹ (e.g., 1-2, 2-2.5, 2.5-3, 3-4 MVcm⁻¹). The polarization field may be selected together with the thickness (since their product equals the voltage drop across a QW). In some implementations, the product of QW thickness and polarization field across a QW is in a range of 0.1-1V (e.g., 0.1-0.3V, 0.25-0.5V, 0.5-0.75V, 0.75V-1V, less than 1V, less than 0.5V, less than 0.3V). In some implementations, the aforementioned values are obtained despite the QW having a composition In(x)Ga(1-x)N with x>0.2 (e.g., >0.25, >0.3, >0.4). In an implementation, a QW has a composition In(x)Ga(1-x)N with x>0.3 and a thickness t>1 nm, it is grown pseudomorphically on a base region with composition In(y)Ga(1-y)N with y>0.05, and/or the voltage drop across the QW is less than 0.5V as a result of a given configuration of parameters including: y, t, and the composition of layers surrounding the QW.

Some implementations include an underlayer, e.g., a layer configured to improve an IQE of the active region by incorporating defects. The underlayer may include In, it may be a continuous InGaN or AlInGaN or AlInN layer and/or a superlattice of In-containing compounds. Alternatively, implementations may not include a separate underlayer, e.g., if respective In concentrations of other layers (i.e., base layer, InGaN n-layers and barriers) already captures point defects effectively.

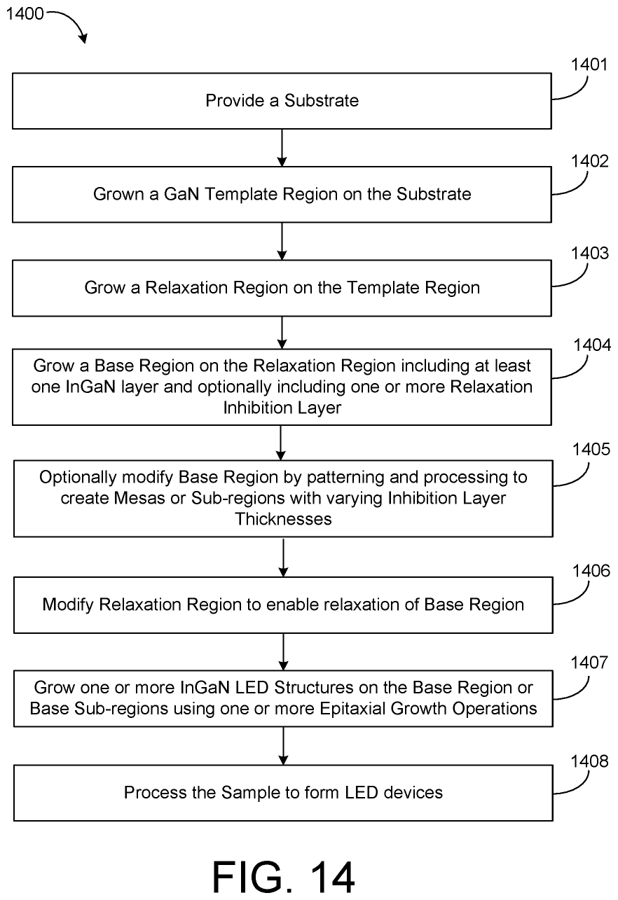

FIG. 14 is a flowchart illustrating an example process flow for producing LEDs according to some implementations, such as those described herein. At block 1401, a substrate is provided. At block 1402, a GaN buffer region is grown on the substrate. At block 1403, a relaxation region is grown pseudomorphic to the buffer region. At block 1404, one or more layers of the base region are grown pseudomorphic to the buffer region, including at least one InGaN layer and, in some implementations, one or more relaxation-inhibition layers among other layers as described herein. At block 1405, the base region is modified by patterning and processing. In some implementations, the processing operations include patterning the relaxation-inhibition layer to create sub-regions with different relaxation-inhibition layer thicknesses, as shown in FIG. 13A. In other implementations, the processing operations include patterning and etching the base region into mesas. In other implementations other processes may be included, or processes can be omitted at the various blocks of FIG. 14. At block 1406, the relaxation region is modified to make it compliant such that the base region or sub-regions can relax. At block 1407, one or more LED structures are grown on the base region or sub-regions using one or more epitaxial growth operations as described herein. At block 1408, the resultant structure is processed to form LED devices. Some operations are optional, and some operations could be omitted or re-ordered.

In some implementations, an etch operation is performed to remove epitaxial material from an LED region after regrowth. The etch operation may be a selective chemical etch, including KOH, H₃PO₄ and/or other type of etch, and may etch some crystal planes faster than others. For instance, the etch it may be a dry etch (including ICP, RIE), it may be a photo-chemical, an electro-chemical, or a photo-electro-chemical etch. The etch may etch non-polar facets (including m and/or a) a faster rate than it etches c-plane facets (including +c). Such an etch process may be used to remove sidewall material from a mesa, without removing top material.

In some implementations, LED region growth occurs conformally, with material grown on top and sides of a mesa or patterned base sub-regions. An etch operation can then be performed to remove the sidewall material while leaving the top material. The etch operation may be performed until the p-type material and active region material of the sidewall have been removed. It may expose the n-type material of the LED region, or the material of the base region. The top surface may be covered or otherwise protected before the etch operation, such that only the sidewall material is removed. The structure after etching may have substantially vertical sidewalls. The etch may be selected to result in a high crystal quality with low defects (e.g., dangling bonds), to reduce sidewall recombination. The sidewall may further be passivated (e.g., by a dielectric layer) after growth to reduce recombination. The etch may be employed to control the lateral dimensions of the lateral structure. In some implementations, the etch removes defective material from the sidewalls. The sidewall material may have a defect (including threading dislocation, misfit dislocation, dangling bond) and the etch may remove material until the defect is absent from the mesa or base sub-region.

In some implementations, the etch removes material which emits light at an unwanted wavelength. In one example, a mesa or sub-region has a light-emitting region perpendicular to its axis (e.g., a disk-like active region in the case of a circular sub-region), and the emission wavelength of the active region is inhomogeneous radially (i.e., it varies from center to edge), resulting in a first FWHM (e.g., full width at half maximum) of emission; the etch removes material near the periphery, resulting in a second FWHM narrower than the first. In another example, the LED region growth is conformal to a mesa or base sub-region and the top and sidewalls of the active region emit at different wavelengths, and the etch removes sidewall material so that emission comes (e.g., only comes) from the top part of the active region.

Epitaxial layers may have tensile or compressive strain. In some implementations, an In(x)Ga(1-x)N layer, grown on GaN or on an In(y)Ga(1-y)N layer with x>y, has a compressive strain. Layers with tensile strain may be grown in the vicinity of layers with compressive strain, to balance the strain. Tensile strain may, for instance. be achieved by adding Al to a III-nitride compound (e.g., using an AlGaN layer, an AlInN layer, an AlInGaN layer with appropriate composition). For instance, an AlGaN barrier may be grown in the vicinity of an InGaN quantum well. In some implementations, a layer with a compressive misfit strain e1 is grown in the vicinity of a layer with a tensile strain e2, and 0.25<|e1/e2|<4 (e.g., 0.5<|e1/e2|<2). A vicinity may be 10 nm or less (e.g., 5 nm or less, 2 nm or less, 1 nm or less).

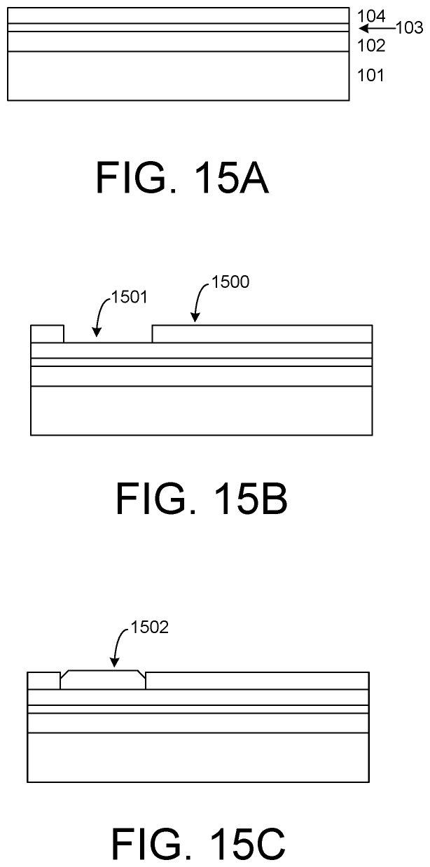

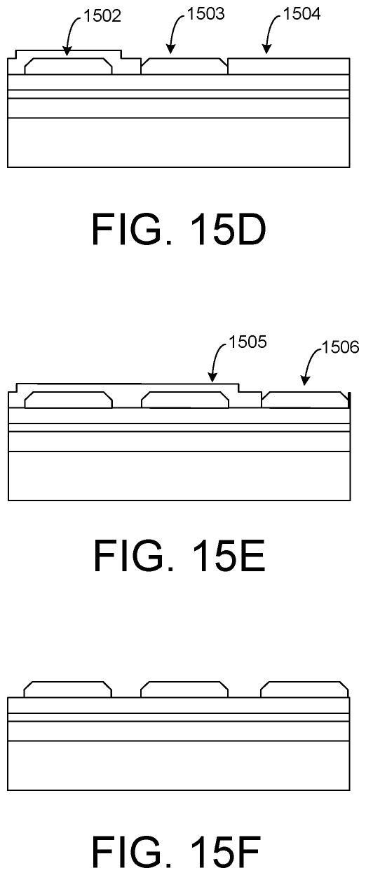

In some implementations, a relaxation region can include a single region and strain state. FIGS. 15A-15F are diagrams schematically illustrating a process flow for obtaining LEDs in accordance with one or more implementations, such as on a substrate as shown in FIG. 15A. For instance, the example of FIG. 15A is a relaxed template including a base region having at least one InGaN layer 104. The base region overlays a strain-relaxation region 103, a template region 102, and a substrate 101 (e.g., a semiconductor wafer, an epitaxial substrate, etc.). In the example, the strain-relaxation region 103 has been modified to enable relaxation of a base region lattice constant, such that the lattice constant of the layer 104 is larger than that of the template region 102.

As shown in FIG. 15B, a first selective area growth mask 1500 is formed and at least one aperture 1501 is opened in the first selective area growth mask 1500, exposing a growth surface of the InGaN layer 104. As shown in FIG. 15C, at least one LED device 1502, including at least an n-type region, a p-type region, and a light-emitting region, is grown (regrown) on the exposed growth surface of the InGaN layer 104 in the aperture 1501. As illustrated in FIG. 15D, the first growth mask 1500 is then removed, and a second growth mask 1504 is deposited, such that is overlays the first plurality of LED devices. At least one apertures is formed and at least one other LED device 1503 is grown (regrown). As shown in FIG. 15E, the second growth mask 1504 is then removed and a third growth mask 1505 is deposited, which overlays the at least one LED device 1502 and the at least one other LED device 1503. At least one aperture is formed and at least one LED device 1506 is grown (regrown). Then, as shown in FIG. the third growth mask 1505 is removed. In example implementations, the first at least one LED device 1502 can emit a spectrum characterized by a peak wavelength λ₁. The second at least one other LED device 1503 can emit a spectrum characterized by a peak wavelength λ₂. The third at least one LED device 1506 can emit a spectrum characterized by a peak wavelength λ₃. In some implementations, λ₁<λ₂<λ₃.

In some implementations, one or more of growth masks are not removed from the epitaxial template. In some implementations, the growth mask material may be selected from silicon dioxide, silicon nitride, alumina, tungsten, and molybdenum among others. In some implementations, the growth mask may include multiple layers of different compositions. For example, a first growth mask may include a silicon nitride layer capped with tungsten, while second and third growth masks are tungsten. Tungsten is removable with a peroxide-based etch with a high selectivity to silicon nitride, which allows for selective removal of tungsten without removal of silicon nitride. In some implementations, the LED device regions partially overgrow their respective growth mask.

In an example implementation, a first selective area growth (SAG) mask including a first SAG mask material is provided. A plurality of apertures for red, green, and blue LED devices are fabricated in the first SAG mask using a single lithographic patterning operation and a wet or dry etch process. A second SAG mask is then deposited on the template wafer overlaying the first SAG mask. The second SAG mask includes a second SAG mask material which is different from the first SAG mask material, and which can be removed with a wet or dry etch having a high selectivity relative to the first SAG mask material. The second SAG mask exposes a first plurality of apertures in the first SAG mask while overlaying a second and third plurality of apertures. A first plurality of LED devices that, when operating, emit light at a first peak wavelength is grown via selective area growth in the first plurality of apertures. The second SAG mask is then selectively removed with a wet or dry etch. A third SAG mask including the second SAG mask material is then deposited on the template wafer overlaying the first SAG mask and the first plurality of LED devices. The third SAG mask exposes the second plurality of apertures in the first SAG mask while overlaying the first and third plurality of apertures. A second plurality of LED devices that, when operating, emit light at a second peak wavelength is grown via selective area growth in the first plurality of apertures. The third SAG mask is then selectively removed with a wet or dry etch. A fourth SAG mask including the second SAG mask material is then deposited on the template wafer overlaying the first SAG mask and the first and second plurality of LED devices. The fourth SAG mask exposes a third plurality of apertures in the first SAG mask while overlaying the first and second plurality of apertures. A third plurality of LED devices that, when operating, emit light at a third peak wavelength is grown via selective area growth in the third plurality of apertures. The fourth SAG mask is then selectively removed with a wet or dry etch.

For implementations with a single relaxation region the spatial variation of the in-plane lattice constant may not vary strongly across the template wafer. That is, there should not be lateral domains of differing lattice constant after relaxation nor should there be large gradients in the in-plane lattice constant across the wafer. Strong variation in the in-plane lattice constant across wafer may have at least two negative effects. First, a degree of indium incorporation driven by strain relaxation may vary across wafer leading to a larger variation in LED peak wavelength across wafer. Second, large variation in strain state across wafer may result in a larger variation in device performance across wafer as the relaxed template is a large contributor to improved performance in long wavelength devices. A high degree of uniformity of an in-plane lattice constant for the relaxed template is achieved by controlling several properties of the relaxed template. First, composition and thickness of the one or more layers in the base region may be well controlled. Large variations in composition will lead to large variations in the equilibrium lattice constant of the base region layers, which, with other aspects being equal, will result in large variations in the relaxed lattice constant across wafer. Variation in the thickness of layers will have a similar effect. Secondly, the degree of modification of the relaxation region may be uniform across the wafer such that a uniform degree of relaxation is achievable by the base region. The uniformity of the degree of modification of the relaxation region can be controlled by controlling the uniformity of the relaxation layer thickness, composition, and doping to a high degree.

In some implementations, the strain-relaxation region 103 and the base region 106 layer thicknesses, compositions, and doping levels vary by no more than 10% (or less than 5%) of the median across-wafer values when excluding a region at the wafer edge with a width of 1 cm or less. Base region, relaxation region, and LED device layer thicknesses and compositions can be characterized using X-ray diffraction, secondary ion mass spectrometry (SIMS), scanning electron microscopy (SEM), transmission electron microscopy (TEM), scanning transmission electron microscopy (STEM), and photoluminescence (PL) and cathodoluminescence (CL) mapping. Doping profiles of base region, relaxation region, and LED device layers can be characterized with standard SIMS techniques. In-plane lattice constants of base region and other layers in the strain-relaxed template can be characterized using glancing incidence X-ray diffraction and X-ray diffraction reciprocal space maps.

Composition of the one or more InGaN layers in the base region 106 may be selected to minimize absorption of light emitted from one or more of corresponding LED devices. A base region including one or more InGaN layers of high composition may reduce, to a high degree, a compressive strain for green and red emitting LED device layers but have bandgap energies less than the energy of light emitted by a blue LED device. The base region may then act as an absorber of the blue LED light and would contribute to poor external quantum efficiency in the blue LED devices. Base region composition may also be selected to prevent one or more the LED devices from being placed under large tensile strain. As an example, a base layer with high InN content may be selected such that quantum wells in green-emitting LED devices are under negligible strain and wells in red-emitting LED devices are under significantly reduced compressive strain relative to growth on a relaxed GaN template. Such a configuration may place quantum wells with lower InN content than the green wells under tensile strain which could lead to device layer cracking and higher defect density.

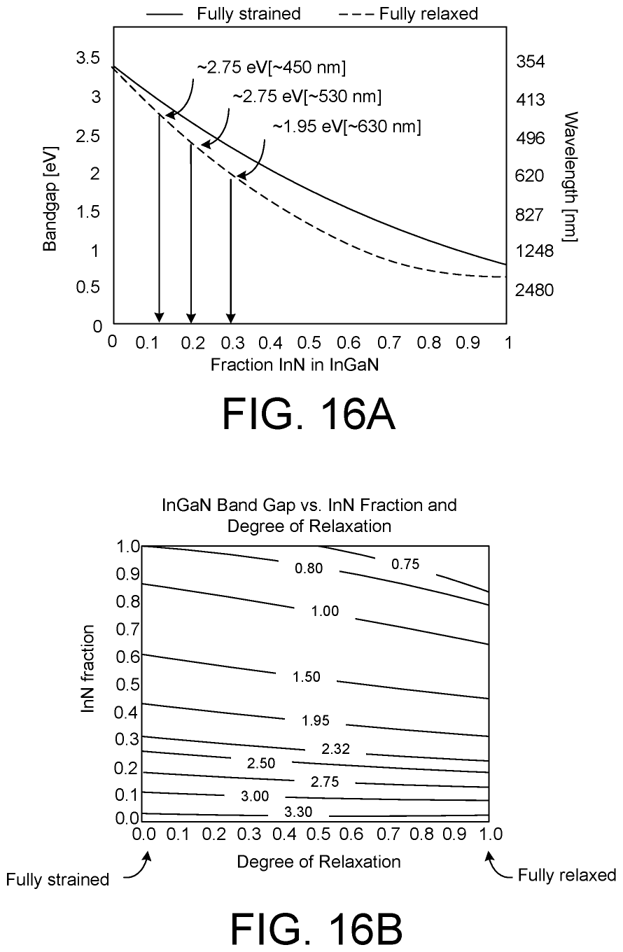

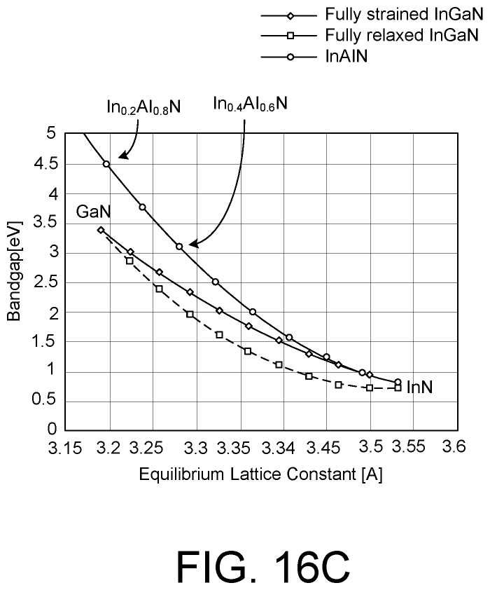

FIGS. 16A-16C are graphs illustrating bandgaps and lattice constants calculated for various InGaN and InAlN alloys based on described material parameters. For instance, FIG. 16A illustrates bandgap as a function of InN fraction for InGaN alloys that are fully strained to relaxed GaN, as well as bandgap for fully strain-relaxed InGaN alloys. Three bandgaps are called out in FIG. 16A, 2.75 electron-volts (eV), 2.32 eV, and 1.95 eV corresponding to light emission wavelengths of ˜450 nm, ˜530 nm, and ˜630 nm, respectively. In some implementations, for one or more InGaN layers in a base region to not be absorbing light from a blue (˜450 nm emitting) LED, the base layer InGaN layers may have an In fraction ≤˜0.18 (for InGaN layers fully strained to GaN) and an In fraction ≤˜0.12 (for InGaN layers that are fully relaxed). For a green LED (emitting ˜530 nm light), a compositional range can be ˜0.2-˜0.3, and for a red LED (emitting ˜630 nm light) a compositional range can be ˜0.3-˜0.42.

FIG. 16B illustrates calculated bandgap for InGaN alloys as a function of InN content and degree of relaxation, where a degree of relaxation of 0 and 1 correspond to fully strained to relaxed GaN and fully strain-relaxed, respectively. FIG. 16C plots bandgap as a function of equilibrium lattice constant for InGaN films fully strained to relaxed GaN as well as fully strain-relaxed. Further, FIG. 16C also shows values for substantially strained InAlN alloys.

Although reference is made to InGaN layers, other compounds may be suitable (e.g., AlInGaN, AlInN), so long as they provide a suitable strain. For instance, the base region 106 of a strain-relaxed template may be AlInN having an in-plane lattice constant equal to that of InGaN with a desired content; such a base region reduces lattice mismatch with InGaN light-emitting layers, as would happen for an InGaN base region. InAlN and InAlGaN alloys have larger bandgaps than InGaN alloys with the same equilibrium lattice constant. Use of InAlN or InAlGaN alloys in the base region allows for larger base-region lattice constants to be achieved without significant absorption of shorter wavelength light such as ˜450 nm light emitted by a blue LED. For example, for one or more InAlN layers in a base region to not be absorbing of light from a blue (˜450 nm emitting) LED, the base layer InAlN layers may have InN fraction ≤˜0.45 when fully strained to GaN. The equilibrium lattice constant of In_{0.45}Al_{0.55}N is similar to In_{0.32}Al_{0.68}N, which has a fully strained bandgap of ˜2.25 eV and would absorb 450 nm light significantly. Therefore, by using InAlN or InAlGaN containing base regions, larger lattice constant base regions may be achieved while minimizing absorption of LED light (e.g., blue LED light) in the base region.

Threading dislocation, stacking faults, misfit dislocations, inversion domains, and other extended crystallographic defects can be characterized and quantified using a variety of techniques. TEM can be used to image the defects, count their density, and determine their origin within the template structure. Cathodoluminescence (CL) can be used to image the defects, count their density, and measure their lateral extent. Microfluorescence (MF) microscopy can be used to image the defects, count their density, and measure their lateral extent, though spatial resolution for MF microscopy is significantly lower than for CL.

Some implementations include mesas (e.g., as shown in FIGS. 8A-11B). While one or more of these configurations may be discussed with respect to the examples described herein, it will be appreciated that the described aspects of the various implementations may be generally applied.

In some implementations, top surface of mesas can be substantially flat. For instance, a transition from sidewall to top surface occurs with no slanted sidewall or a slanted sidewall of limited extent (such as less than 500 nm, less than 100 nm, less than 50 nm, less than 10 nm).

A top surface of the base region may be oriented substantially along the 0001 (+c) direction, or along the 000-1 (−c) direction. It may be substantially free of domain inversions (i.e., domains where the polarity switches between +c and −c). In some implementations, at least 90% (e.g., 95% or more, 99% or more) of the top surface of the base region is of a constant polarity.

A thickness of the base region may be in a range from 10 nm to 10 microns (e.g., 10 nm to 1 micron, 100 nm to 10 microns, 100 nm to 3 microns).

Some implementations include base regions including mesas (e.g., have lateral structures with lateral dimensions on the order of one to a few microns). Some implementations include base regions having a plurality of sub-regions with different lattice constants at the top surface of the base region. The lateral dimensions of the mesas and sub-regions may be in a range from 500 nm to 50 microns (e.g., 500 nm to 1 micron, 500 nm to 5 microns, 500 nm to 3 microns).

In some implementations, an active region extends substantially to edges of a micro-LED, but configuration of the active region varies laterally. A thickness of an active layer may decrease near an edge of the mesa. The thickness of an active layer at the edge of a mesa may be less than 90% (e.g., 80% or less, 50% or less) of the thickness of the same active layer at the center of the mesa. Composition of an active layer may decrease near the edge of the mesa. For instance, In composition of an active layer at the edge of a mesa may be smaller than the In composition of the same active layer at the center of the mesa by at least 1% (e.g., 2% or more, 5% or more).

Such variations may facilitate a reduced injection of carriers near the edges of the mesa. In some implementations, an exclusion region exists around the edge of the LED. An area of the exclusion region may be between 5% and 50% of the total area of the active region; it may be at least 5% (e.g., 10% or more, 20% or more, 30% or more) and less than 50% (e.g., 30% or less, 20% or less). Less than 20% (e.g., 10% or less, 5% or less, 1% or less) of the total emitted light may originate from the exclusion region.

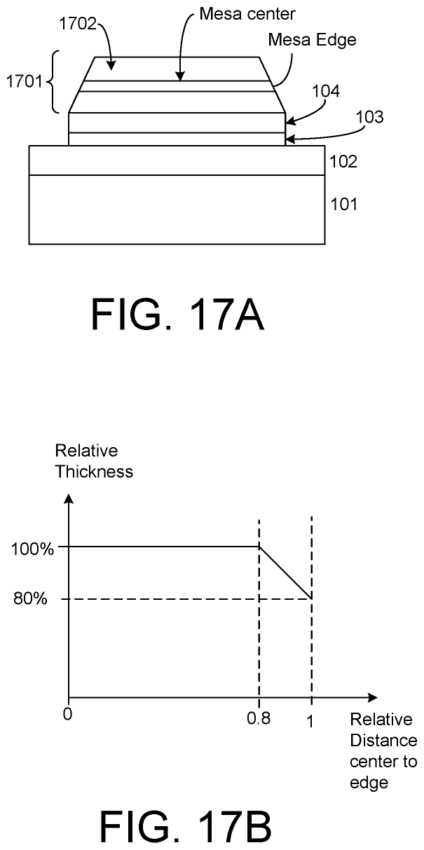

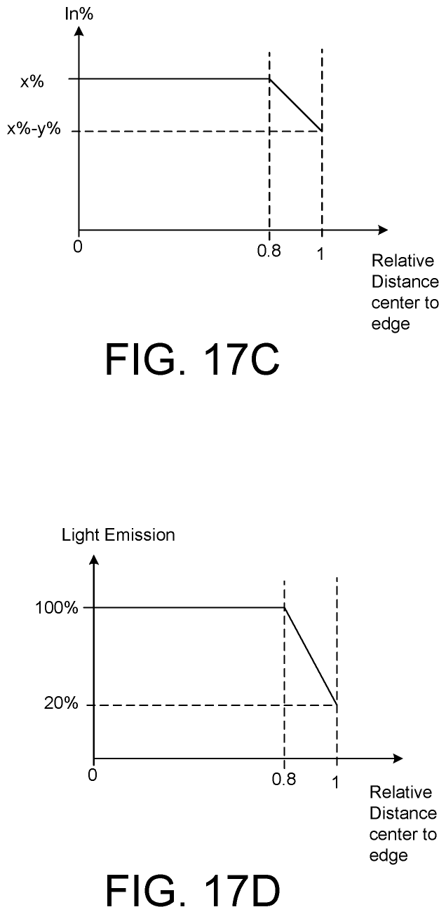

FIGS. 17A-17D are diagrams and graphs illustrating lateral variations in active region properties, e.g., from a center structure to an edge structure. For instance, FIG. 17A illustrates a center structure and an edge structure of LED layers 1701 and an LED active region 1702. FIGS. 17B-17D illustrate variation of properties may vary from center to edge, as a function of the relative lateral distance (0 being the center and 1 the edge). A property may be substantially constant from the center to a distance (0.8 in this example, but other values are possible, such as about 0.7, about 0.9), and then vary from the distance to the edge. For example, as shown in FIG. 17B, a thickness of the active region 1702 may decrease by at least 5% (e.g., 10% or more, 20% or more, 30% or more, 40% or more, 50% or more). As shown in FIG. 17C, an In composition of the active layer 1702 may decrease by at least 1% (e.g., 2% or more, 5% or more, 10% or more). As shown in FIG. 17D, an intensity of light emission may decrease by at least 50% (e.g., 80% or more, 90% or more, 95% or more).

Mesas of varying dimensions (e.g., mesas of FIGS. 8A-11B) may be formed on a same substrate. In some implementations, three dimensions are present, which respectively correspond to red/green/blue emission. In some implementations, the varying dimensions are obtained by selectively reducing dimensions of some mesas (e.g., by masking some mesas and etching other mesas).

Varying lateral dimensions, or strain state may facilitate a difference in In incorporation during growth (regrowth) of a LED, as described herein, and may result in simultaneous growth of LEDs with varying emission wavelengths (e.g., red/green/blue), as taught herein. Differences in strain state may lead to a different lattice pulling effect, with more In being incorporated above base material having lower strain. In some implementations, an active layer is grown and a difference in In % across different mesas or base-layer sub-regions is at least 5% (e.g., 10% or more, 15% or more). This can facilitate a difference in emission wavelength of at least 50 nm (e.g., 100 nm or more).

After growth of base and LED regions, the resulting semiconductor structure can be processed into LED devices. A variety of device architectures can be employed, including lateral, vertical, flip-chip.

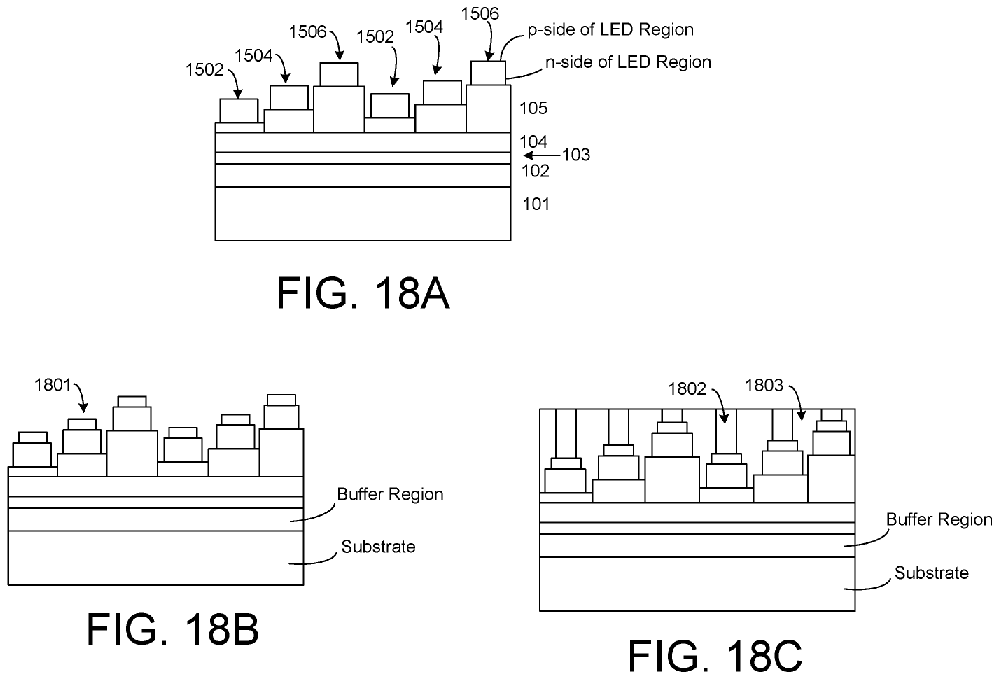

FIGS. 18A-18C are diagrams illustrating an example process flow for producing LED devices on a relaxed template with a patterned base region. FIG. 18A illustrates a relaxed template that includes a substrate 101, a template region 102, a strain-relaxation region 103, and a patterned base region having one or more InGaN layers 104 and, in some implementations, one or more relaxation-inhibition layers 105. LED devices are grown epitaxially on the regrowth surfaces of the patterned base-region. For instance, a first plurality of LED devices 1502, a second plurality of LED devices 1503, and a third plurality of LED devices 1506 are grown, where respective peak emission wavelengths of the three pluralities are different from each other. In example implementations, the LED devices 1502, 1503 and 1506 have an n-doped and a p-doped region, with an active region between the n and p-doped regions.

As shown in FIG. 18B, p-contacts 1801 are deposited on the LED devices. In some implementations, the p-contacts include one or metals, such as Ni, Pd, Pt, Ag, and the like. In some implementations, the p-contacts 1801 include transparent conductive oxides such as ZnO, indium tin oxide, and the like, or combinations of transparent conductive oxides and metals.

As shown in FIG. 18C, in this example, a planarizing dielectric 1803 is deposited. In some implementations, surface of the planarizing dielectric 1803 is flattened and smoothed using a polishing process such as chemical mechanical polishing. Vias are etched through the planarizing dielectric 1803 to expose the p-contacts 1801. Metal 1802 is deposited to fill the vias using one or more of the techniques of physical vapor deposition, chemical vapor deposition, and/or electroplating. In some implementations, a surface of the metal 1802 filling the vias is flattened and smoothed using a polishing process such as chemical mechanical polishing.

One or more techniques can be employed to remove the substrate and template layers and expose the n-side of the base region. Such techniques include, but are not limited to a selective chemical etch, a grind and polish process, a dry etch process, a laser lift-off (LLO) process, a mechanical break/cleave, an ion-implantation and break/cleave (akin to a smart cut process), and/or a laser ablation or micro-ablation process (e.g., stealth process), possibly followed by a mechanical break.

A number of example aspects, approaches and/or features of strain-relaxed LED (e.g., micro-LED) devices are now described. It will be appreciated that these described aspects, approaches and/or features can apply to one more or more of the various implementations described herein. For instance, in some implementations, the template region has a larger bandgap than the base region and LED layers (e.g., active and/or light-emitting layers). For instance, the template region can be GaN and the base region and LED layers can include layers with InGaN compositions. This facilitates selective LLO using a radiation source (such as a pulsed laser) with a wavelength that is not absorbed by the template region but is absorbed by the base region or one or more of the LED layers. For instance, the wavelength can be 390 nm, which is not significantly absorbed by GaN but is significantly absorbed by In0.1GaN. In some implementations, a specific layer of the base region has a high In composition and is absorbing, whereas other InGaN layers of the base region and LED layers are not absorbing. For instance, the LED structure can include layers of InxGa(1-x)N with x≤0.1, and the base region can contain at least one sacrificial layer with In0.2Ga0.8N. In this example, LLO can be performed with a laser which is absorbed by In0.2GaN but not by In0.1GaN. The sacrificial layer may be grown during the LED region growth.

In some implementations, modification of the strain-relaxation region to make it compliant can result in it being highly optically absorbing. For example, a relaxation region including an InGaN material with high indium content, which is decomposed into regions (inclusions, etc.) of metallic In by exposure to high temperature conditions will be highly absorbing of optical radiation across a wide range of wavelengths including ultraviolet, visible, and infra-red wavelengths. This facilitates selective LLO using a radiation source (such as a pulsed laser) which is not absorbed by the substrate and template region but is absorbed by the modified relaxation region.

In other implementations, the relaxation region can include an InGaN material with high indium content, which is decomposed into regions (inclusions, etc.) of metallic In by exposure to high temperature, can be selectively removed by wet etching with acids such as one or more of: hydrochloric acid, nitric acid, aqua regia, among others. In some implementations, the In and Ga metal layer is removed using a chlorine-based plasma etch process such as ICP, RIE, CAIBE, RIBE, or the like.

In some implementations, A photo-chemical etch (or photo-electro-chemical etch) may also be used, with a layer of a specific composition having high absorption for the photons and prone to the etch. The transparency/absorption refers to a wavelength used in the etch operation. For instance, an example implementation can include a transparent substrate, a transparent layer (e.g., GaN), a base InGaN layer with a large absorption, and LED layers. Such a structure can be illuminated through the substrate (which may be polished and/or have an optical finish), where the illumination goes through the transparent layer and is absorbed by the base layer, causing etching of the base layer.

A wet etch can be used to remove the buffer or the substrate (including implementations where the substrate is Si).

In some implementations, several techniques are used successively. For instance, an LLO process can be used to remove the template layer, exposing a portion of the base region or LED layers. A material-removing operation (e.g., mechanical polish, dry etch, etc.) can then be used to thin down the exposed base region or LED layers to a desired thickness, before a contact is made to the polished surface. The base region or LED layers can be thinned to obtain a planar surface. The base region or LED layers can be thinned to reach a doped layer. In some implementations, a part of the base region or LED layers is undoped and a part is doped; a material-removing process is employed to remove undoped material and reach the doped material.

In some implementations, the base region may include voids. This makes the connection of the LED layers to the underlying layer weak, and the LED layers are amenable to breaking near the voids.

In some implementations, a surface preparation operation is performed on a doped surface of the LED layers or base region before a contact is formed to the doped surface. The treatment may include a clean operation (including by a solvent, an acid, a base), e.g., a wet etch, a dry etch. The surface may be n-doped; the treatment may be a dry etch containing O or Si which facilitates higher doping of the surface, thereby causing a lower contact resistance when the contact is formed to the surface. In some implementations, a surface-prepared region has higher doping than the semiconductor before surface preparation. In some implementations, a surface of an InGaN base region is exposed; the base region has a doping level D (e.g., about 1E16, 5E16, 1E17, 5E17, 1E18, 5E19, 1E19) after epitaxy; the surface treatment can increase the doping to at least 10 times D. This may facilitate good (e.g., low) contact resistance despite moderate doping during growth. The moderate doping may be desirable e.g., to limit doping-induced strain. The base region doping level may be selected to ensure low-enough resistivity of a NW subpixel at a desired current density. In some implementations, the maximum operation current density is moderate (e.g., less than 50 A·cm⁻² or 10 A·cm⁻² or 1 A·cm⁻² or 0.1 A·cm⁻²); therefore, a moderate doping level may be acceptable.

Although reference is made to InGaN layers with respect to implementations described herein, other compounds may be suitable (e.g., AlInGaN, AlInN) so long as they provide a suitable strain. For instance, the base region of a strain-relaxed template may be AlInN having an in-plane lattice constant equal to that of InGaN with a desired content. Such a base region can reduce lattice mismatch with InGaN light-emitting layers, as would happen for an InGaN base region. The approaches described herein can also be applied to material systems other than the III-Nitride system, including III-V and II-VI compound semiconductors.

For instance, other crystals (including semiconductors and insulating crystals) with a suitable lattice constant may be used as base material to achieve reduced active region strain as disclosed herein. In some implementations, a substrate material has a crystal symmetry and a lattice constant which facilitate the growth of InGaN with a reduced strain. The symmetry may be hexagonal (including a wurtzite symmetry). The lattice constant may facilitate a misfit strain less than half of the misfit strain for pseudomorphic growth on GaN. In some implementations, an InGaN base region is grown on the substrate material and an InGaN active region is grown on the InGaN base region. The InGaN base region may be substantially relaxed or pseudomorphic with the substrate material. The base region may have a base region In composition, and the active region may have an active region In composition, wherein the active region In composition is higher than the base region In composition by at least 3% (e.g., 5% or more, 8% or more, 10% or more, 12% or more, 15% or more, 20% or more, 25% or more, 30% or more).

An in-plane lattice constant generally refers to a lattice constant in a direction perpendicular to growth (e.g., perpendicular to an epitaxial growth direction). For instance, in the common case where a wurtzite material is grown along the c-axis (or a direction close to the c-axis), the in-plane lattice constant refers to the lattice constant perpendicular to the c-axis.

When element compositions are disclosed herein, they can include fractional compositions of elements of a given group (e.g., column III or column V). For instance, In0.2GaN stands for In0.2Ga0.8N, with the sum of the In and Ga atom numbers being equal to the N atom numbers.

Some implementations have lateral structures (e.g., mesas) whose cross-section is not circular (e.g., square, rectangle, hexagon, ellipse, etc.). Such structures can, nevertheless, be characterized by a typical lateral dimension, e.g., if a corresponding cross section has an area A, the typical lateral dimension is defined herein as 2*sqrt(A/pi). This definition coincides with the diameter for a circular cross-section.

Example LED emitters described herein may be used in displays, including micro-displays. A micro-display typically has multiple pixels, each having a red, a green and a blue subpixel. A distance between two pixels may be less than 20 μm (e.g., 15 μm, 10 μm, 7 μm, 5 μm, 3 μm). A distance between two subpixels may be less than 10 μm (e.g., 7.5 μm, 5 μm, 3.5 μm, 2.5 μm, 1.5 μm). A micro-display may be integrated in a display system, such as an augmented or virtual reality headset. Individual subpixels of a display may be operated electrically to emit light and form an image.

Strain, strain relaxation, and lattice constants can be measured by various techniques. These techniques include X-ray diffraction, X-ray reciprocal space map (RSM), grazing incidence X-ray, transverse electron microscopy, Raman spectroscopy, and so forth. For instance, an RSM measurement along an appropriate direction (such as the (10-15) direction in III-Nitrides) can indicate whether a layer is pseudomorphic, partially or fully relaxed, and enable a measurement of the in-plane lattice constant.

Such measurements can also define a degree of relaxation for a second material grown on a first material. A layer that is pseudomorphic is 0% relaxed. A layer having an in-plane lattice constant equal to its bulk equilibrium value is 100% relaxed. A layer grown on a first material whose lattice constant is halfway between the first material (e.g., GaN) and its equilibrium value is 50% relaxed. In other words, relaxation degree=(a2−a1)/(a2_relaxed−a1)

Accordingly, example implementations can include an InGaN material (e.g., a base region such as the base region 106) with a sufficient In composition (e.g., at least 5%, 10% or more, 15% or more, 20% or more, 25% or more, 30% or more) and with a sufficient relaxation degree with respect to GaN (e.g., at least 30%, 50% or more, 60% or more, 70% or more, 80% or more). A surface of the InGaN material/base region may provide such a relaxation. Additional layers may be grown on top of the relaxed surface, for instance light-emitting layers/quantum wells. Such active layers may have a sufficient In composition (e.g., at least 20%, 30% or more, 35% or more, 40% or more, 50% or more, 60% or more) and a limited relaxation degree with respect to the InGaN material (e.g., 50% or less, 40% or less, 30% or less, 20% or less, 10% or less).

In some implementations, several LED regions (for instance, of varying colors, such as red-green-blue) are present. References to an LED region also apply more generally to a plurality of LED regions with different characteristics (e.g., color).

Various aspects of example implementations are summarized as follows. In general, a first aspect features a display emitter including: three pluralities of sub-regions each corresponding to a sub-pixel of a display, respectively emitting blue, green, and red light during operation of the display emitter, each sub-region including: a relaxation region grown on a GaN template layer comprising one or more epitaxial layers which decouple the lattice constant of layers overlaying the relaxation region from the GaN template layer; a base region grown on the relaxation region, comprising one or more epitaxial layers with at least one layer having an InGaN composition with at least 5% In, and having at least one regrowth surface which is partially or fully relaxed, having a base lattice constant greater than the bulk value of GaN and less than or equal to the lattice constant of the layer in the base region with the largest bulk lattice constant value; and an LED region regrown pseudomorphic with the at least one regrowth surface, including at least one light-emitting layer having an InGaN composition with at least 10% In and having a misfit strain between the light-emitting layer and the regrowth surface less than half of a misfit strain between the light-emitting layer and the regrowth surface. The LED region having a threading dislocation density below 1E8 cm⁻². The light-emitting layer is pseudomorphic with the regrowth surface, having an active region lattice constant which is within 0.1% of the base lattice constant. The LED device sub-pixels having a low electrical leakage of . . . .

Implementations may include one or more of the following features and/or features of other aspects.

The base region can be formed by hydride vapor phase epitaxy (HVPE), metal organic chemical vapor deposition (MOCVD), or molecular beam epitaxy (MBE).

The LED region can be regrown by metal organic chemical vapor deposition (MOCVD) or MBE.

The base and active region lattice constants can be in-plane lattice constants.

The base region can have a homogeneous composition equal to the InGaN composition.

The three pluralities of sub-regions can contain base regions of uniform strain state, with the base-region lattice constant varying between sub-regions by less than 0.1% of the bulk lattice constant for the base region layer with the largest bulk lattice constant.

The three pluralities of sub-regions can contain base regions of different strain states, with the magnitude of the sub-region lattice constant for the red-light emitting sub-pixels being larger than that of the green-light emitting sub-pixels and with the magnitude of the sub-region lattice constant for the green-light emitting sub-pixels being larger than that of the blue-light emitting sub-pixels.

The base region can be grown on a planar GaN template or on a GaN template layer including lateral structures with lateral dimensions less than 10 micrometers.

The base region can include lateral structures with lateral dimensions less than 10 micrometers, and where relaxation of the base region material occurs within the lateral structures.

The relaxation regions can be fully strained to the GaN template layer during epitaxial growth of the base-region and the relaxation process can be induced in situ or ex situ to the epitaxial reactor.

In general, a first aspect features a display emitter including: three pluralities of sub-regions each corresponding to a sub-pixel of a display, respectively emitting blue, green, and red light during operation of the display emitter, each sub-region including: a relaxation region grown on a GaN template layer comprising one or more epitaxial layers which decouple the lattice constant of layers overlaying the relaxation region from the GaN template layer; a base region grown on the relaxation region, comprising one or more epitaxial layers with at least one layer having an InGaN composition with at least 5% In, and having at least one regrowth surface which is partially or fully relaxed, having a base lattice constant greater than the bulk value of GaN and less than or equal to the lattice constant of the layer in the base region with the largest bulk lattice constant value; and an LED region regrown pseudomorphic with the at least one regrowth surface, including at least one light-emitting layer having an InGaN composition with at least 10% In and having a misfit strain between the light-emitting layer and the regrowth surface less than half of a misfit strain between the light-emitting layer and the regrowth surface. The LED region having a threading dislocation density below 1E8 cm⁻². The light-emitting layer is pseudomorphic with the regrowth surface, having an active region lattice constant which is within 0.1% of the base lattice constant. The LED device sub-pixels having a low electrical leakage of . . . .

Implementations may include one or more of the following features and/or features of other aspects.

The one or more relaxation-inhibition layers can be grown epitaxially in the same growth operation as growth of the base layers or in a separate epitaxial growth operation.

The one or more relaxation-inhibition layers can be formed by hydride vapor phase epitaxy (HYPE), metal organic chemical vapor deposition (MOCVD), or molecular beam epitaxy (MBE).

The one or more relaxation-inhibition layers are patterned using standard lithographic techniques and dry etching techniques such as reactive ion etching (RIE), inductively coupled plasma (ICP) etching, chemically assisted ion beam etching (CAIBE), reactive ion beam etching (RIBE), and the like.

In another aspect, features can include a display device, including three pluralities of LED devices. One or more (e.g., each) of the pluralities of LED devices can be configured to emit light at a peak wavelength, λ, in the visible spectrum. The first plurality of LED devices are configured to emit at a first peak wavelength, λ₁, in the visible spectrum. The second plurality of LED devices are configured to emit at a first peak wavelength, λ₂, in the visible spectrum. The third plurality of LED devices are configured to emit at a first peak wavelength, λ₃, in the visible spectrum. λ₁, λ₂, and λ₃ are different from each other. At least one LED device from the three pluralities of LED devices can be grouped together and constitute a single pixel of the display device.

It will be understood, for purposes of this disclosure, that when an element, such as a layer, a region, or a substrate, is referred to as being on, disposed on, disposed in, connected to, electrically connected to, coupled to, or electrically coupled to another element, it may be directly on, connected or coupled to the other element, or one or more intervening elements may be present. In contrast, when an element is referred to as being directly on, directly disposed on, directly disposed in, directly connected to or directly coupled to another element or layer, there are no intervening elements or layers present. Although the terms directly on, direct in, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to, vertically adjacent to, or horizontally adjacent to.

Some implementations may be implemented using various semiconductor processing and/or packaging techniques. Some implementations may be implemented using various types of semiconductor processing techniques, such as epitaxial growth processes, associated with semiconductor substrates and materials including, but not limited to, for example, silicon (Si), gallium arsenide (GaAs), gallium nitride (GaN), silicon carbide (SiC), and/or so forth.

While certain features of various example implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. A method of producing an optoelectronic device, the method comprising:
forming a first layer on a substrate, the first layer being a mechanically-compliant layer;
forming a second layer, the mechanically-compliant layer being disposed between the second layer and the substrate;
performing a relaxation operation to facilitate a release of strain energy in the second layer by the mechanically-compliant layer,
the mechanically-compliant layer, the second layer and the relaxation operation being configured such that a surface of the second layer has an extended defect density below a predetermined value; and
forming a light-emitting region, the second layer being disposed between the light-emitting region and the substrate, the extended defect density being below the predetermined value results in a leakage resistance in an active region of the light-emitting region that is higher than 10 milliohms per centimeter-squared (mOhm/cm²).

2. The method of claim 1, wherein the leakage resistance is greater than 100 mOhm/cm².

3. The method of claim 1, wherein the extended defect density is less than 1×10⁹/cm2.

4. The method of claim 1, further comprising forming a defect-reduction layer, the mechanically-compliant layer being disposed between the defect-reduction layer and the substrate.

5. The method of claim 1, wherein:
the mechanically-compliant layer has a first defect density;
the light-emitting region has a second defect density; and
the second defect density is less than one-tenth of the first defect density.

6. The method of claim 1, wherein the relaxation operation is performed during an epitaxial growth operation.

7. The method of claim 1, wherein the optoelectronic device has a peak internal quantum efficiency of at least 20%.

8. The method of claim 1, wherein the optoelectronic device operates at a current density J and has a leakage current of less than J/10.

9. The method of claim 1, wherein the optoelectronic device operates at a current density J and has an ideality factor of less than 5 at a current density of J/10.

10. The method of claim 1, wherein the mechanically-compliant layer includes at least one of:
a nano-porous structure;
voids with dimensions more than 1 nm and less than 1 um;
metallic inclusions;
extended defects; or
semiconductor material with an in-plane inhomogeneity in a composition of one atomic species of at least 1%.

11. An optoelectronic device comprising:
a semiconductor template having a first lattice constant;
a strain-relaxation layer disposed on the semiconductor template, the strain-relaxation layer having a second lattice constant which is at least 1% larger than the first lattice constant;
a defect reduction layer disposed on the strain-relaxation layer; and
a light-emitting diode (LED) region including an active region, the LED region being disposed on the defect reduction layer and having a third lattice constant that is substantially equal to the second lattice constant,
a surface density of a defect being smaller above the defect reduction layer in a direction of epitaxial growth of the optoelectronic device than below the strain-relaxation layer in the direction of epitaxial growth, such that the LED region has an ideality factor of less than 5 when operating at a current density of 1 A/cm2.

12. The optoelectronic device of claim 11, wherein the strain-relaxation layer includes a plurality of pores respectively having a size between 5 nanometers (nm) and 500 nm.

13. The optoelectronic device of claim 11, wherein an extended defect density of the optoelectronic device is less than 1×10⁹/cm2.

14. The optoelectronic device of claim 11, further comprising a defect-reduction layer, the strain-relaxation layer being disposed between the defect-reduction layer and the semiconductor template.

15. The optoelectronic device of claim 11, wherein:
the strain-relaxation layer has a first defect density;
the LED region has a second defect density; and
the second defect density is less than one-tenth of the first defect density.

16. The optoelectronic device of claim 11, wherein the strain-relaxation layer is a grown epitaxial layer.

17. The optoelectronic device of claim 11, wherein the strain-relaxation layer includes at least one of:
a nano-porous structure;
voids with dimensions more than 1 nanometer and less than 1 micron;
metallic inclusions;
extended defects; or
semiconductor material with an in-plane inhomogeneity in a composition of one atomic species of at least 1%.

18. An optoelectronic device comprising:
a semiconductor template having a first in-plane lattice constant;
a strain-relaxation region disposed on the semiconductor template, the strain-relaxation region including:
an inhomogeneous region having a material composition with an in-plane inhomogeneity with a characteristic in-plane distance between 1 nm and 1000 nm; and
a strain-relaxed top surface having:
dimensions of at least 500 nanometers (nm)×500 nm; and
a second in-plane lattice constant that is different from the first in-plane lattice constant; and
a light-emitting diode (LED) region disposed on the strain-relaxed top surface, the LED region being pseudomorphic with the strain-relaxed top surface.

19. The optoelectronic device of claim 18, wherein the second in-plane lattice constant:
is homogeneous;
has a relative variation of less than +/−10% across the strain-relaxed top surface; and
has an average value that is at least 0.01 angstroms larger than the first in-plane lattice constant.

20. The optoelectronic device of claim 18, wherein the in-plane inhomogeneity varies in composition of an atomic element by at least 1%.

21. The optoelectronic device of claim 18, wherein the in-plane inhomogeneity includes at least one of a void, a cavity, a metallic inclusion, or an extended defect.

22. The optoelectronic device of claim 18, further comprising a spacer layer having a thickness of more than 10 nm, the spacer layer being disposed between the inhomogeneous region and the strain-relaxed top surface.

23. A method of producing an optoelectronic device, the method comprising:
growing, on a substrate, a series of layers, including:
at least one relaxation layer under a strain; and
a strain-inhibition layer, the at least one relaxation layer being disposed between the strain-inhibition layer and the substrate;
after growing the series of layers, forming:
a first lateral region with the strain-inhibition layer having a first thickness; and
a second lateral region with the strain-inhibition layer having a second thickness that is greater than the first thickness;
after forming the first lateral region and the second lateral region, performing a relaxation operation, the relaxation layer changing a mechanical structure of the at least one relaxation layer to reduce the strain in the at least one relaxation layer, such that relaxation in the first lateral region is greater than relaxation in the second lateral region; and
forming at least one light-emitting region on at least one of the first lateral region or the second lateral region.

24. The method of claim 23, wherein the strain of the at least one relaxation layer is compressive.

25. The method of claim 23, wherein the at least one relaxation layer includes aluminum indium gallium nitride (AlInGaN) material.

26. The method of claim 23, wherein the at least one light-emitting region is formed after performing the relaxation operation.

27. The method of claim 23, wherein the first thickness and the relaxation operation are configured such that the at least one relaxation layer has a predetermined in-plane lattice constant in the first lateral region.

28. The method of claim 23, wherein the first thickness is zero, the strain-inhibition layer being fully removed in the first lateral region.

29. The method of claim 23, wherein the at least one relaxation layer includes an indium gallium nitride (InGaN) layer.

30. The method of claim 23, wherein performing the relaxation operation includes forming, in the at least one relaxation layer, at least one of:
a plurality of nano-pores; or
a plurality of voids;
a plurality of metallic inclusions;
a plurality of extended defects; or
semiconductor material with an in-plane inhomogeneity in a composition of one atomic species of at least 1%.
